(19) United States
(12) Patent Application Publication
(10) Pub. No.: US 2012/0068242 A1
(43) Pub. Date: Mar. 22, 2012

(54) SEMICONDUCTOR DEVICES AND METHODS OF FABRICATING THE SAME

(76) Inventors: Seung-Mok SHIN, Yongin-si (KR); Ju-Eun Kim, Seoul (KR)

(21) Appl. No.: 13/234,534

(22) Filed: Sep. 16, 2011

(30) Foreign Application Priority Data
Sep. 16, 2010 (KR) 10-2010-0091300

(51) Int. Cl. H01L 29/788; H01L 29/02

(52) U.S. Cl. 257/315; 257/618; 257/324; 257/E29.3; 257/E29.002

(57) ABSTRACT

A semiconductor device includes horizontal patterns on a substrate and the horizontal patterns have at least one opening therein, a pad pattern in an upper region of the opening, an insulating gap fill structure in the opening, the insulating gap fill structure is between the pad pattern and the substrate, and the insulating gap fill structure includes a first gap fill pattern and a second gap fill pattern. The first gap fill pattern includes a first oxide and the second gap fill pattern includes a second oxide, and the second oxide has a different etching selectivity from that of the first oxide. The device further includes a semiconductor pattern that is between a sidewall of the gap fill structure and sidewalls of the horizontal patterns and between a sidewall of the pad pattern and the sidewalls of the horizontal patterns.

### CROSS-REFERENCE TO RELATED APPLICATION

Korean Patent Application No. 10-2010-0091300, filed on Sep. 16, 2010, in the Korean Intellectual Property Office, and entitled: “Semiconductor Devices and Methods of Fabricating the Same,” is incorporated by reference herein in its entirety.

### BACKGROUND

Research is being conducted with respect to reducing the size of semiconductor devices, for example, with respect to reducing a planar area of elements that constitute a semiconductor device.

### SUMMARY

Embodiments may be realized by providing a semiconductor device that includes horizontal patterns on a substrate, the horizontal patterns having at least one opening therein, a pad pattern in an upper region of the at least one opening, an insulating gap fill structure in the at least one opening, the insulating gap fill structure being between the pad pattern and the substrate and the insulating gap fill structure including a first gap fill pattern and a second gap fill pattern, and a semiconductor pattern between a sidewall of the gap fill structure and sidewalls of the horizontal patterns and between a sidewall of the pad pattern and the sidewalls of the horizontal patterns. The first gap fill pattern includes a first oxide and the second gap fill pattern includes a second oxide, and the second oxide has a different etching selectivity from that of the first oxide.

The semiconductor pattern may include a bottom part interposed between the gap fill structure and the substrate. The first gap fill pattern may include a first silicon oxide and at least a first type of impurity in the first silicon oxide, and the second gap fill pattern may include a second silicon oxide and at least a second type of impurity in the second silicon oxide. The second type of impurity may be different from the first type of impurity. The first gap fill pattern may include a first silicon oxide and hydrogen and chlorine as impurities in the first silicon oxide, and the second gap fill pattern may include a second silicon oxide and at least one of nitrogen, hydrogen, and carbon as impurities in the second silicon oxide.

A top surface of the first gap fill pattern may include a middle part that is concavely recessed, and the second gap fill pattern may be interposed between the first gap fill pattern and the pad pattern. The second gap fill pattern may have a pillar shape, and the first gap fill pattern may surrounds a sidewall of the second gap fill pattern.

The at least one opening may be in a shape of a hole in the horizontal patterns. The at least one opening may be in a shape of a line when viewed from a plan view, and the opening may cross the horizontal patterns.

The horizontal patterns may include a plurality of conductive patterns and a plurality of insulating patterns alternately stacked. An uppermost layer of the horizontal patterns may be one of the plurality of insulating patterns, and a lowermost conductive pattern of the plurality of conductive patterns may be spaced apart from the substrate.

A gate insulating layer may be between the conductive patterns and the semiconductor pattern. The gate insulating layer may extend between the conductive patterns and the insulating patterns. The gate insulating layer may be between the semiconductor pattern and the conductive patterns and may be between the semiconductor pattern and the insulating patterns.

The semiconductor pattern may correspond to a channel region of a transistor. The gate insulating layer may include a data storage layer data of a non-volatile memory cell and the conductive patterns may correspond to gate electrodes.

Embodiments may also be realized by providing a semiconductor device that includes horizontal patterns on a semiconductor substrate, the horizontal patterns including alternately stacked gate electrodes and insulating patterns, at least one opening penetrating the horizontal patterns, the opening exposing the semiconductor substrate, a pad pattern in an upper region of the at least one opening, the pad pattern including a first crystalline silicon, a gap fill structure in the at least one opening, the gap fill structure being between the pad pattern and the semiconductor substrate. The gap fill structure includes a first gap fill pattern containing a first oxide and a second gap fill pattern containing a second oxide, and the second oxide has a different etching selectivity from that of the first oxide. The device also includes a semiconductor pattern including a second crystalline silicon, the semiconductor pattern being between a sidewall of the gap fill structure and sidewalls of the horizontal patterns and being between the pad pattern and the sidewalls of the horizontal patterns, impurity regions in the pad pattern and the semiconductor pattern adjacent to the pad pattern, and a gate insulating layer between the semiconductor pattern and the gate electrodes, the gate insulating layer including a data storage layer.

In the at least one opening, sidewalls of the gate electrodes may not be vertically aligned with sidewalls of the insulating patterns. In the at least one opening, sidewalls of the gate electrodes may be vertically aligned with sidewalls of the insulating patterns.

Embodiments may also be realized by providing a stacked structure including a plurality of conductive patterns and a plurality of insulating patterns alternately stacked, at least one opening in the stacked structure, a semiconductor pattern on sidewalls of the at least one opening, the semiconductor pattern including crystalline silicon, and an insulating gap fill structure on the semiconductor pattern and in the at least one opening. The insulating gap fill structure includes a first gap fill pattern including a first oxide, and a second gap fill pattern including a second oxide, the second oxide having a different etching selectivity from that of the first oxide.

The first gap fill pattern may be a first film in the at least one opening and the second gap fill pattern may be a second film in the at least one opening, the second film being different from the first film. The second film may be a flowable oxide film or a tonen silazene film. A pad pattern may be in an uppermost portion of the at least one opening, the pad pattern, the first gap fill pattern, and the second gap fill pattern may completely fill the at least one opening. The crystalline silicon of the semiconductor pattern may be a crystalline silicon film, and the first and second gap fill patterns may be directly on the crystalline silicon film.

### BRIEF DESCRIPTION OF THE DRAWINGS

Features will become apparent to those of ordinary skill in the art by describing in detail exemplary embodiments with reference to the attached drawings, in which:

FIG. 1 illustrates a plan view of a semiconductor device according to an exemplary embodiment;

FIGS. 2, 3, 4, 5, 6, 7A, 7B, 7C, and 8 illustrate vertical cross-sectional views of semiconductor devices according to exemplary embodiments;

FIG. 9 illustrates a plan view of a semiconductor device according to an exemplary embodiment;

FIGS. 10A and 10B illustrate vertical cross-sectional views of semiconductor devices according to exemplary embodiments;

FIG. 11 illustrates a plan view of stages in a method of fabricating a semiconductor device according to exemplary embodiments;

FIGS. 12A-12K illustrate vertical cross-sectional views of stages in a method of fabricating a semiconductor device according to an exemplary embodiment;

FIGS. 13A and 13B illustrate vertical cross-sectional views of stages in a method of fabricating a semiconductor device according to an exemplary embodiment;

FIGS. 14A to 14D illustrate vertical cross-sectional views of stages in a method of fabricating a semiconductor device according to an exemplary embodiment;

FIGS. 15A to 15C illustrate vertical cross-sectional views of stages in a method of fabricating a semiconductor device according to an exemplary embodiment;

FIG. 16 illustrates a plan view of a semiconductor device according to an exemplary embodiment;

FIGS. 17A to 17E illustrate vertical cross-sectional views of stages in a method of fabricating a semiconductor device according to an exemplary embodiment;

FIG. 18 illustrates a block diagram of an electronic system including a semiconductor device according to an exemplary embodiment;

FIG. 19 illustrates a block diagram of a memory card including a non-volatile memory device according to an exemplary embodiment; and

FIG. 20 illustrates a block diagram of a data processing system according to an exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. When any element of the inventive disclosure appears in more than one drawing, it is denoted by the same reference numeral in each drawing. It will also be understood that when a layer or element is referred to as being “on” another layer or element, it can be directly on the other layer or element, or intervening layers or elements may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present.

Exemplary embodiments may be described with reference to schematic plan views or cross-sectional views. As such, variations from the shapes of the illustrations, as a result, e.g., of manufacturing techniques and/or tolerances, are to be expected. Thus, example embodiments should not be construed as being limited to the particular shapes of regions illustrated herein, but are to include deviations in shapes that result from, e.g., a manufacturing process. Thus, the regions illustrated in the drawings are schematic in nature and are not intended to limit the scope.

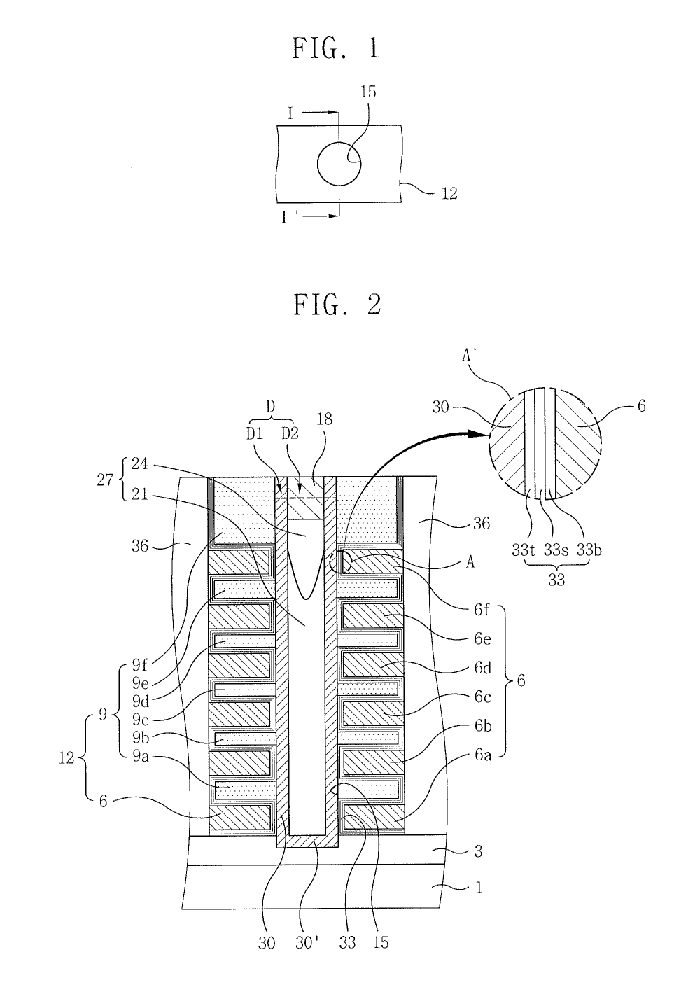

FIG. 1 illustrates a plan view of a semiconductor device according to exemplary embodiments, and FIGS. 2 to 8 illustrates vertical cross-sectional views taken along line I-I′ of FIG. 1.

FIG. 2 illustrates a vertical cross-sectional view of a semiconductor device according to one exemplary embodiment. Accordingly, a semiconductor device according to one embodiment will be described with reference to FIGS. 1 and 2.

Referring to FIGS. 1 and 2, a substrate 1 may be provided. The substrate 1 may be a semiconductor substrate. The substrate 1 may include a memory cell region or a cell array region where memory cells are formed or are to be formed. The substrate 1 may include a peripheral circuit region where peripheral circuits, e.g., for operating the memory cells, may be formed. The substrate 1 may be formed of a semiconductor wafer, e.g., a wafer having a single crystalline structure such as a P-type silicon wafer. The substrate 1 may include a semiconductor film, e.g., a silicon on insulating (SOI) layer.

An impurity region 3 may be provided in the substrate 1. The impurity region 3 may have various structures, e.g., a pocket well structure or a multiple well structure. The impurity region 3 may include a P-type well. The impurity region 3 may be formed by implanting impurities into the substrate 1.

The impurity region 3 may include, e.g., an N+ type region and/or P-type region. The N+ type region may be a high-concentration N-type region defined as a source region of a transistor on its surface region. The impurity region 3 may include a P-type well region and a high-concentration N-type source region formed in a part of the well region. The P-type region may be a high-concentration P-type source region.

Stacked patterns, e.g., horizontal patterns 12, may be provided on the substrate 1. Each of the horizontal patterns 12 may extend in a direction that is substantially parallel to a main surface of the substrate 1. For example, the horizontal patterns 12 may be arranged so as to form a stacked structure on the substrate 1. The horizontal patterns 12 may include conductive patterns 6a to 6f and interlayer insulating patterns 9a to 9f. The conductive patterns 6a to 6f may be defined as a conductive structure 6, and the interlayer insulating patterns 9a to 9f may be defined as an interlayer insulating structure 9. However, embodiments are not related thereto. For example, the horizontal patterns 12 may include additional or less conductive patterns 6 and interlayer insulating patterns 9.

The conductive patterns 6a to 6f may be spaced apart from each other by the interlayer insulating patterns 9a to 9f. The conductive patterns 6a to 6f may be interposed between the interlayer insulating patterns 9a to 9f. For example, the conductive patterns 6a to 6f and the interlayer insulating patterns 9a to 9f may be alternately stacked on top of each other to form the horizontal patterns 12. The interlayer insulating patterns 9a to 9f may be formed of an insulating material, e.g., silicon oxide, silicon oxynitride, and/or silicon nitride. The conductive patterns 6a to 6f may be formed of a conductive material, e.g., a polysilicon, a metal, and/or a metal including tungsten.

The uppermost layer of the horizontal patterns 12 may be the interlayer insulating pattern 9f. The conductive pattern 6a may be the lowermost layer of the horizontal patterns 12. The conductive pattern 6a may be spaced apart from the substrate 1. The interlayer insulating patterns 9a to 9f may be formed in varying thickness, e.g., the interlayer insulating pattern 9f may have the greatest thickness and the interlayer insulating pattern 9a may have a thickness that is less than the interlayer insulating pattern 9f and greater than the other interlayer insulating patterns.

One or more openings 15 may penetrate the horizontal patterns 12. The opening 15 may expose a predetermined region of the substrate 1 such that the opening 15 may extend through the entire stacked structure of the horizontal patterns 12. The opening 15 may be in the shape of a hole. When viewed from a plan view, each of the openings 15 may be in the shape of a plate defining the opening 15 in, e.g., a circular or polygonal shape. When viewed from a plan view, each of the horizontal patterns 12 may be in the shape of a line including the opening 15 formed in the middle part thereof. For example, the horizontal patterns 12 may include a plurality of lines shaped patterns extending in planes parallel to each other, and each of the line shaped patterns may include one or more openings 15.

A pad pattern 18 may be provided in an upper region of the opening 15. The pad pattern 18 may be surrounded by sidewalls of the horizontal patterns 12 in the openings 15, e.g., the pad pattern 18 may be surrounded by the sidewalls of the interlayer insulating pattern 9f adjacent to the opening 15. The pad pattern 18 may include, e.g., crystalline silicon. For example, the pad pattern 18 may be formed of a polysilicon layer.

An insulating gap fill structure 27 may be provided at a lower part of the pad pattern 18. The insulating gap fill structure 27 may include, e.g., first and second gap fill patterns 21 and 24 provided therein. The first and second gap fill patterns 21 and 24 may be formed of oxides having different etching selectivities with respect to each other. According to an exemplary embodiment, the second gap fill pattern 24 may be formed of an oxide having a higher etch rate to an oxide etchant than the first gap fill pattern 21. The oxide etchant may be an etching solution containing hydrofluoric acid (HF). However, embodiments are not limited thereto.

The first gap fill pattern 21 may include a first oxide, and the second gap fill pattern 24 may include a second oxide and may be formed by a method different from that used for forming the first oxide of the first gap fill pattern 21. For example, the first gap fill pattern 21 may be formed of a first oxide by using a deposition method, e.g., an atomic layer deposition (ALD) method. The second gap fill pattern 24 may be formed of a second oxide formed using a flowable oxide. For example, the flowable oxide may be a material that is capable of being deposited by a flowable chemical vapor deposition method (F-CVD). The second oxide may be a FCVD oxide (F-CVD) formed by the flowable CVD (F-CVD) method or a Tonen Silazene (TOSZ) formed by a spin coating method. For example, the second oxide may form a flowable oxide film or a Tonen Silazene film. The gap fill structure 27 may include the first gap fill pattern 21 formed of the first oxide by the deposition method such as an ALD and the second gap fill pattern 24 formed of the second oxide using the flowable oxide, and the resultant gap fill structure 27 may be substantially free of and/or may not have a defect, e.g., voids, formed therein. In this regard, the gap fill structure 27 may completely fill a portion of the opening 15 in such a manner that voids are avoided and/or minimized.

According to an exemplary embodiment, both the first and second gap fill patterns 21 and 24 may include silicon (Si) and oxygen (O), and may also include elements different from each other. For example, the first gap fill pattern 21 may include, in addition to Si and O, at least one of hydrogen (H) and chlorine (Cl), and the second gap fill pattern 24 may include at least one of nitrogen (N), H, and carbon (C).

The first and second gap fill patterns 21 and 24 may be formed of silicon oxide containing impurities. The first gap fill pattern 21 may be formed of e.g., silicon oxide (Si—H—Cl—O) containing H and Cl as impurities. The second gap fill pattern 24 may be formed of, e.g., silicon oxide (Si—N—H—C—O or Si—N—H—O) containing at least one of N, H, and C as impurities. The second gap fill pattern 24 may have a lower density than a density of the first gap fill pattern 21.

The first gap fill pattern 21 may have a top surface whose middle part is concavely recessed. For examples, the top surface of the first gap fill pattern 21 may have a U-shape such that the top surface includes an outer rim that is above the middle part of the top surface. The second gap fill pattern 24 may fill, e.g., completely fill, the concave recessed portion of the first gap fill pattern 21. The second gap fill pattern 24 may be interposed between the first gap fill pattern 21 and the pad pattern 18.

A semiconductor pattern 30 may be interposed between the gap fill structure 27 and the opening 15. The semiconductor pattern 30 may also be interposed between a sidewall of the pad pattern 18 and a sidewall of the opening 15. The semiconductor pattern 30 may cover, e.g., substantially entirely cover, the sidewalls and a bottom surface of the opening 15. That is, the semiconductor pattern 30 may be provided to surround a sidewall of the gap fill structure 27 and a sidewall of the pad pattern 18. The opening 15 may be filled, e.g., completely filled, by the semiconductor pattern 30, the gap fill structure 27, and the pad pattern 18.

A bottom part 30′ of the semiconductor pattern 30, i.e., a part of the semiconductor pattern 30 on the bottom surface of the opening 15, may extend from the semiconductor pattern 30 and may be interposed between the gap fill structure 27 and the substrate 1. The bottom part 30′ of the semiconductor pattern 30 may be disposed in a trench formed in the substrate 1 and a bottom surface of the trench corresponds to the bottom surface of the opening 15. The semiconductor pattern 30 and the bottom part 30′ of the semiconductor pattern 30 may be formed as a serially connected layer. The semiconductor pattern 30 may be formed of, e.g., crystalline silicon. For example, the semiconductor pattern 30 may be formed of single silicon or polysilicon.

The substrate 1 and the semiconductor pattern 30 may be formed of different types of crystalline silicon. For example, the substrate 1 may be formed of single crystalline silicon, and the semiconductor pattern 30 may be formed of polysilicon.

A first impurity region D1 may be provided in the semiconductor pattern adjacent to the pad pattern 18. A second impurity region D2 may be provided in the pad pattern 18. The first impurity region D1 may surround the second impurity region D2. The first and second impurity regions D1 and D2 may constitute a high-concentration N+ impurity region D. The N+ impurity region D may be defined as a drain region.

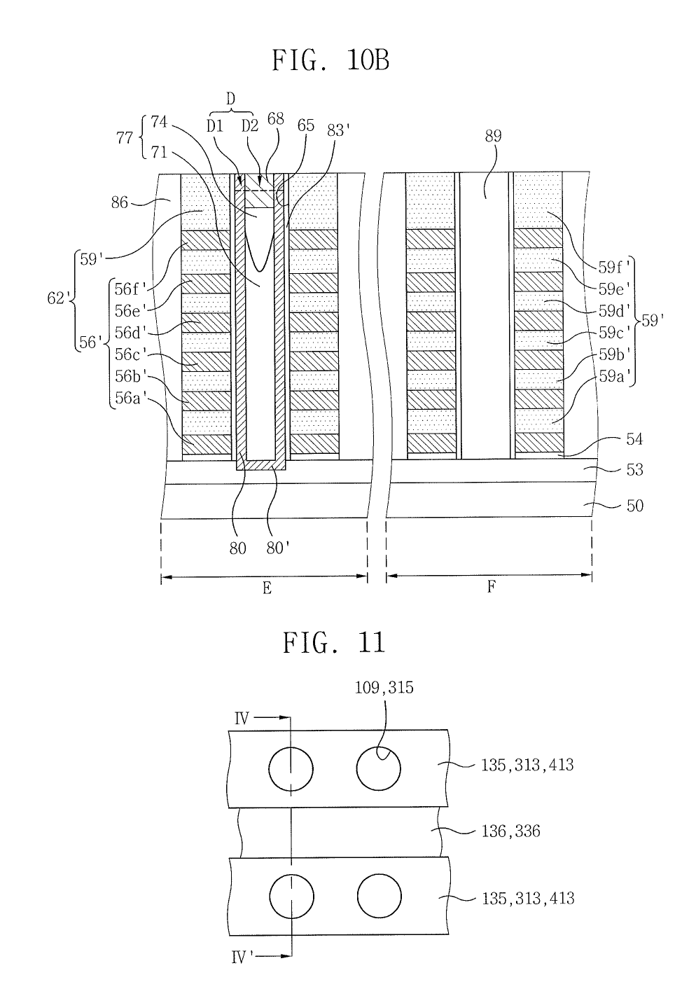

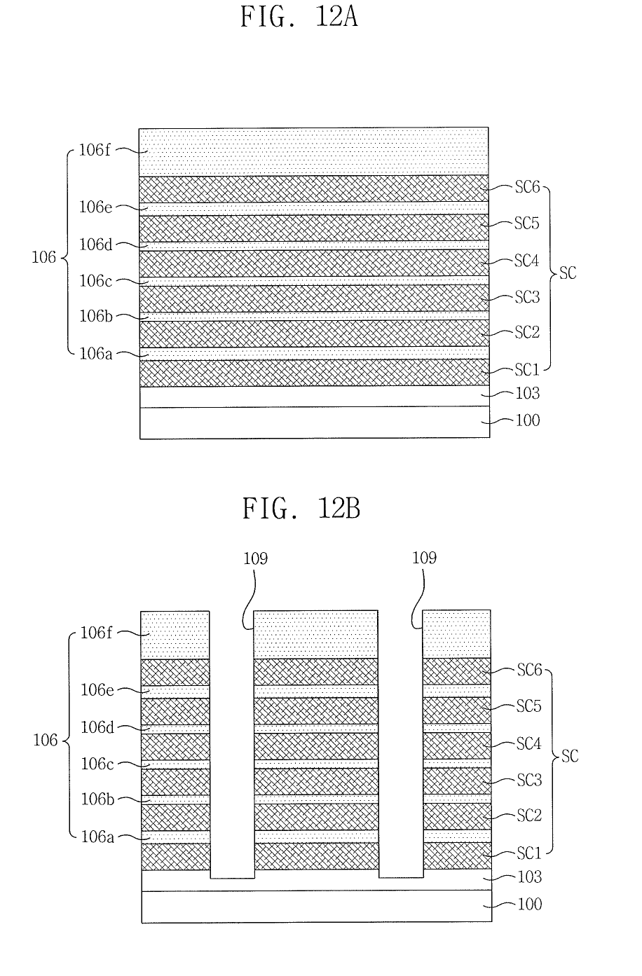

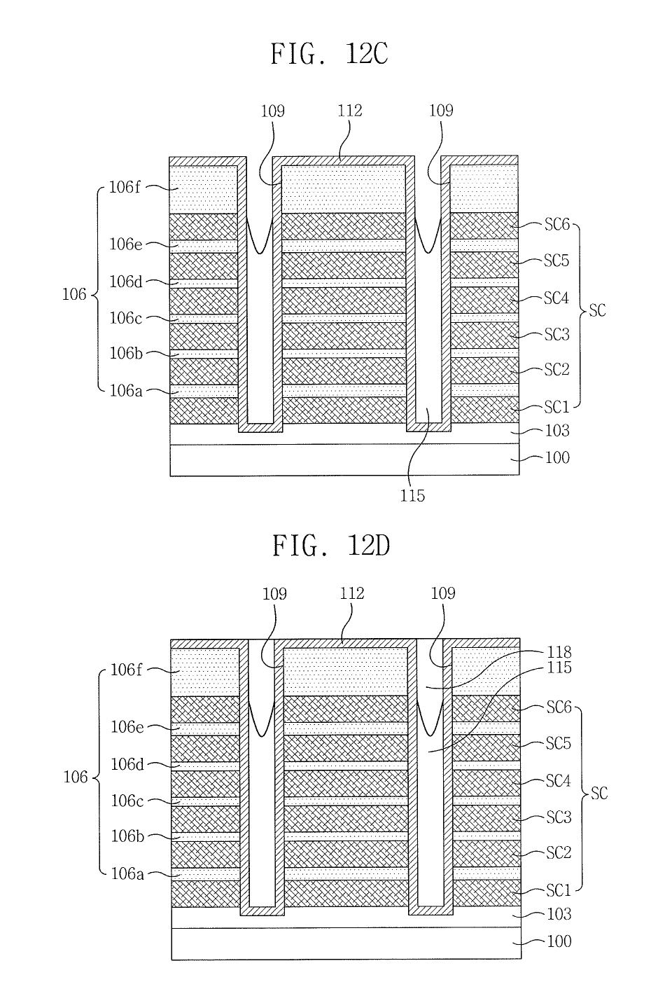

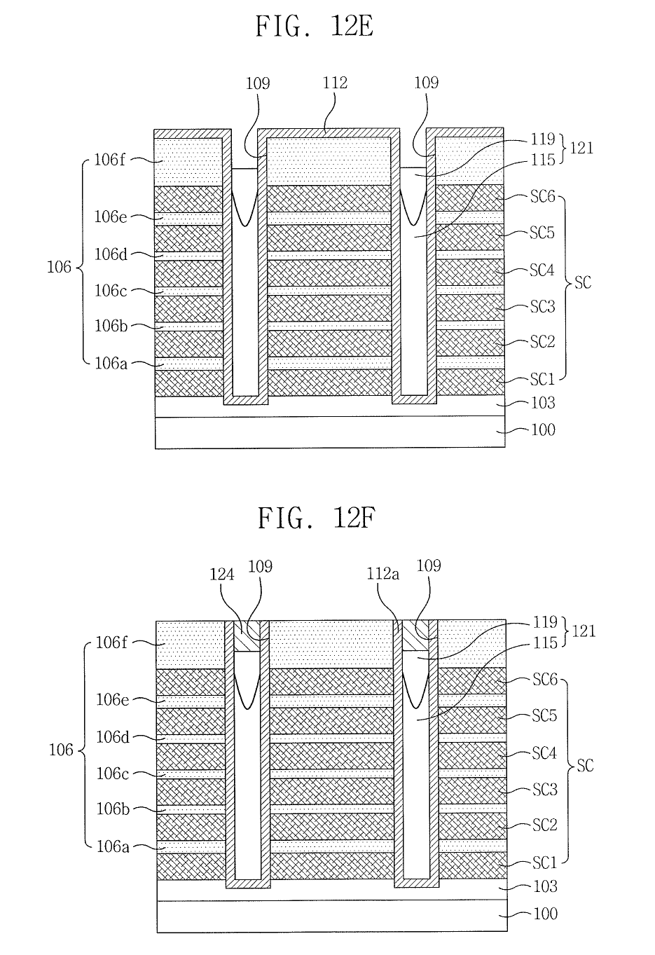

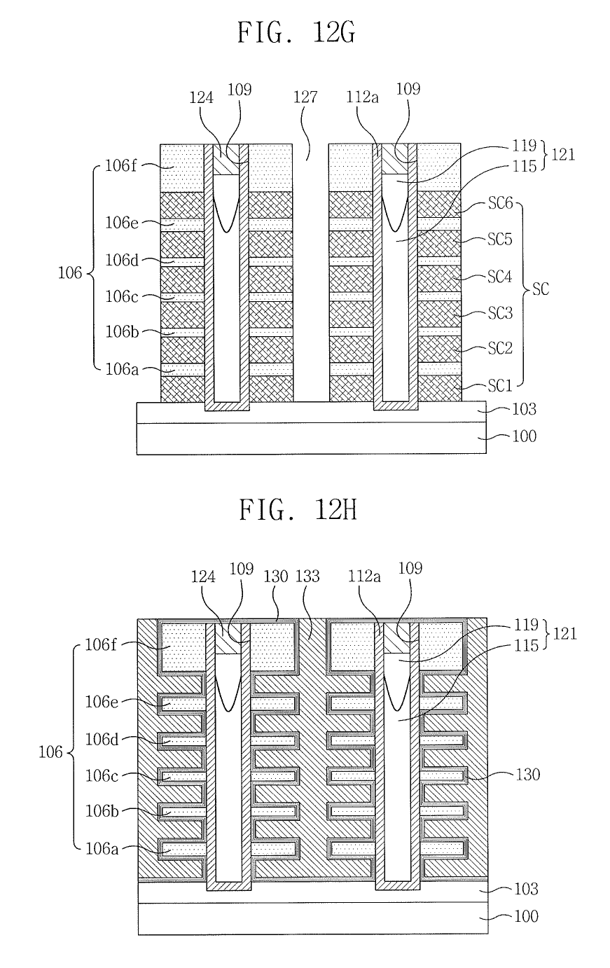

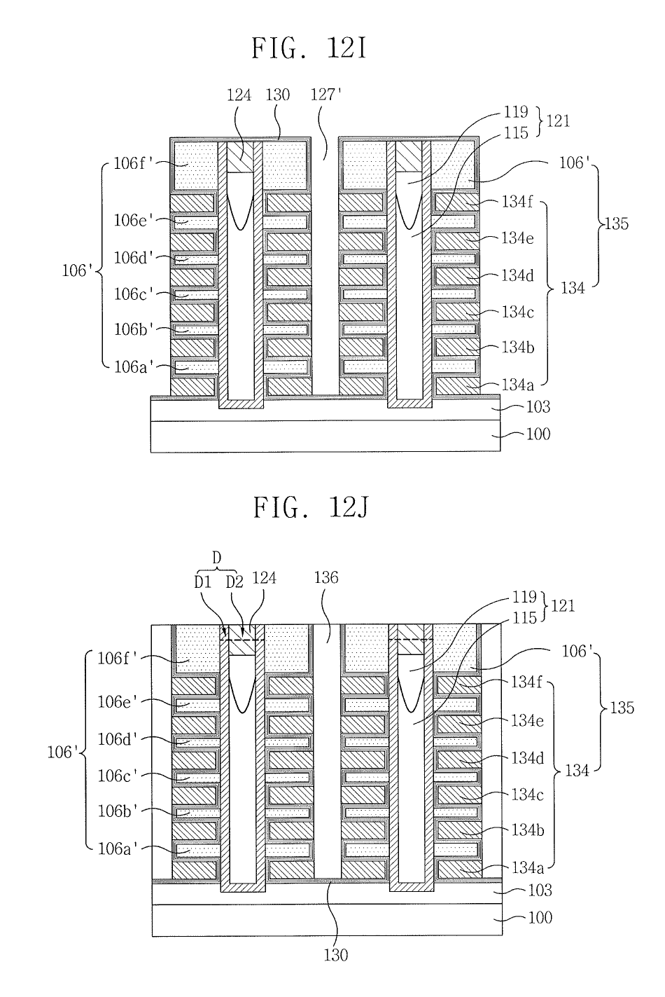

The pad pattern 18 and the semiconductor pattern 30 may form a stable contact with respect to each other. The detailed description thereof will be provided below with reference to FIGS. 12E and 12F.

A gate insulating layer 33 may be interposed between the semiconductor pattern 30 and the conductive patterns 6. The gate insulating layer 33 may include, e.g., a tunnel insulating layer 33t, a data storage layer 33s, and a blocking insulating layer 33b. The tunnel insulating layer 33t, the data storage layer 33s, and the blocking insulating layer 33b may be sequentially stacked on top of each other. The tunnel insulating layer 33t may be adjacent to the semiconductor pattern 30, e.g., may be an outer layer that contacts the semiconductor pattern 30. The blocking insulating layer 33b may be adjacent to the conductive patterns 6, e.g., may be an outer layer that contacts the semiconductor pattern 30. The data storage layer 33s may be interposed between the tunnel insulating layer 33t and the blocking insulating layer 33b.

The tunnel insulating layer 33t may be formed of, e.g., one selected from a silicon oxide layer, a silicon oxynitride (SiON) layer, a nitrogen doped Si oxide layer, and a high-k dielectric group. The high-k dielectric group may be formed of, e.g., a dielectric layer such as an aluminum oxide (AlO) layer, a zirconium oxide (ZrO) layer, a hafnium oxide (HfO) layer, and/or a lanthanum oxide (LaO) layer having a higher dielectric constant than a silicon oxide layer.

The data storage layer 33s may be a layer for storing data, e.g., in a non-volatile memory device such as a flash memory device. For example, the data storage layer 33s may have traps capable of storing charge. Depending on operating conditions, the data storage layer 33s may be formed of, e.g., a material capable of trapping electrons injected from the semiconductor pattern 30 via the tunnel insulating layer 33t and causing retention of the trapped electrons or erasing the trapped electrons. For example, the data storage layer 33s may be formed of at least one selected from the group consisting of a SiON layer, a silicon nitride layer, and a high-k dielectric group. The blocking insulating layer 33b may be formed of at least one selected from the group consisting of a silicon oxide layer and a high-k dielectric group.

The gate insulating layer 33 may be interposed between the semiconductor pattern 30 and the conductive patterns 6, and may extend between the conductive patterns 6 and the insulating patterns 9. The gate insulating layer 33 may be interposed between a lowermost conductive pattern 6a of the conductive patterns 6 and the substrate 1.

In an exemplary embodiment, sidewalls of the conductive patterns 6 may not be vertically arranged, e.g., aligned, with sidewalls of the insulating patterns 9. In other words, sidewalls of the conductive patterns 6 may be offset with respect to sidewalls of the adjacent insulating patterns 9. The sidewalls may be offset with respect to each other due to the placement of the gate insulating layer 33. The sidewalls of the insulating patterns 9 may be vertically arranged, e.g., aligned, with the gate insulating layer 33 formed between sidewalls of the conductive patterns 6 and the semiconductor pattern 30a.

The horizontal patterns 12 may be defined by a gate isolation insulating layer 36. For example, the gate isolation insulating layer 36 may be formed to surround outer sidewalls of the horizontal patterns 12. Adjacent horizontal patterns 12 may be spaced apart by the gate isolation insulating layer 36. The gate isolation insulating layer 36 may be formed of an insulating material, e.g., silicon oxide.

Among the conductive patterns 6, the conductive pattern 6a disposed at the lowermost part may be used as, e.g., a lower selection line (LSL). The conductive pattern 6f disposed at the uppermost part may be used as, e.g., an upper selection line (USL). Conductive patterns 6b to 6e disposed between the LSL and the USL may be used as, e.g., word lines of a non-volatile memory device. The LSL may be a ground selection line, and the USL may be a string selection line.

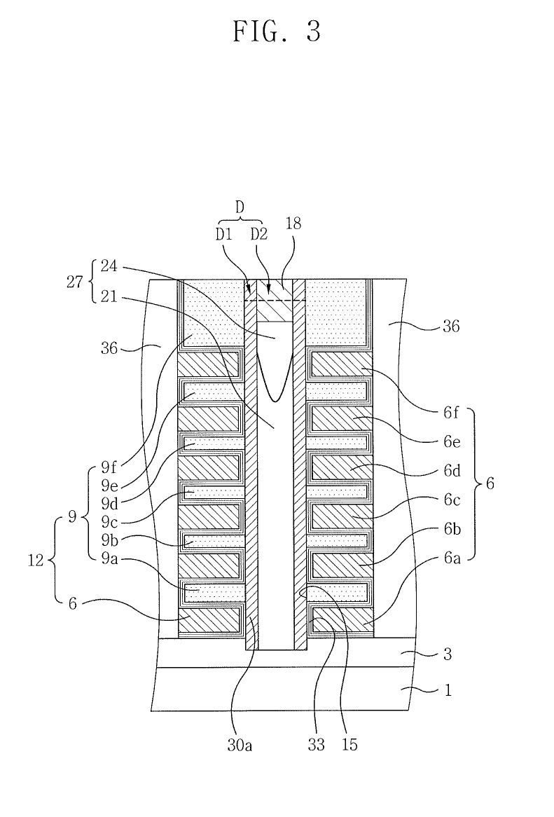

FIG. 3 illustrates a vertical cross-sectional view of a semiconductor device according to another exemplary embodiment. As illustrated in FIG. 3, the semiconductor patterns 30 and 30′ described with reference to FIG. 2 may be modified to form a semiconductor pattern 30a. For example, the modified semiconductor pattern 30a may be formed to surround a sidewall of the gap fill structure 27 and a sidewall of the pad pattern 18, but may not be interposed between the gap fill structure 27 and the substrate 1. Thus, the semiconductor pattern 30a may not be continuously disposed on the bottom surface of the opening 15, e.g., the semiconductor pattern 30a may be excluded on a middle portion of the bottom surface of the opening 15. In other words, a surface or inside of the substrate 1, or the impurity region 3, may be partially exposed through the semiconductor pattern 30a. As such, the substrate 1 or impurity region 3 may be in direct contact with the gap fill structure 27.

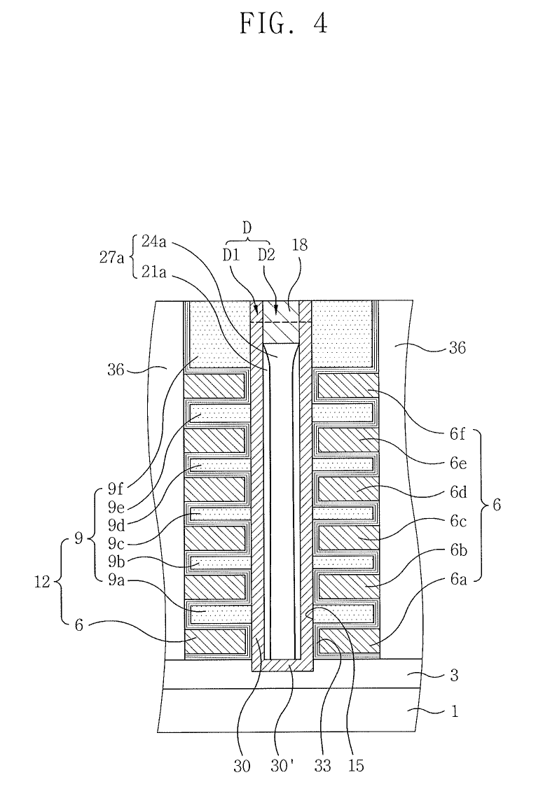

FIG. 4 illustrates a vertical cross-sectional view of a semiconductor device according to still another exemplary embodiment. As illustrated in FIG. 4, the gap fill structure 27 described with reference to FIG. 2 may be modified to a gap fill structure 27a. More specifically, as illustrated in FIG. 4, the modified gap fill structure 27a may include a pillar-shaped second gap fill pattern 24a formed between the pad pattern 18 and the substrate 1. The modified gap fill structure 27a may also include a first gap fill pattern 21a surrounding a sidewall of the second gap fill pattern 24a. An area of the top surface of the pillar-shaped second gap fill pattern 24a may correspond to an area of bottom surface of the pad pattern 18. As such, the second gap fill pattern 24a may be spaced apart from the pad pattern 18 by the top surface of the pillar-shaped second gap fill pattern 24a. Further, an upper portion of the pillar-shaped second gap fill pattern 21a, which includes the top surface thereof, may have a gradually decreasing width such that second gap fill pattern 24a is formed in the area of the decreasing width. The pillar-shaped second gap fill pattern 21a and the second gap fill pattern 24a may extend to the bottom surface of the opening 15.

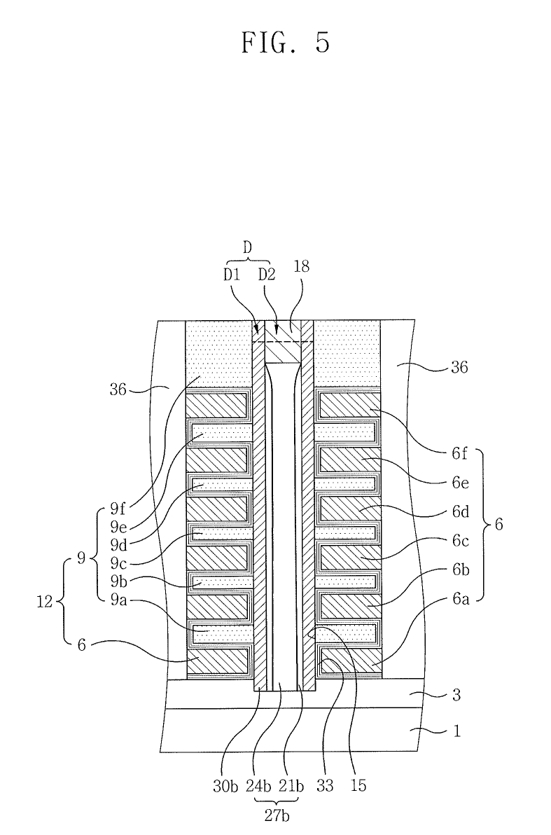

FIG. 5 illustrates a vertical cross-sectional view of a semiconductor device according to yet another exemplary embodiment. As illustrated in FIG. 5, the semiconductor patterns 30 and 30′ and the gap fill structure 27 described with reference to FIG. 2 may be modified to a semiconductor pattern 30b and a gap fill structure 27b. The modified gap fill structure 27b may include a pillar-shaped second gap fill pattern 24b formed between the pad pattern 18 and the substrate 1, e.g., directly contacting the pad pattern. The gap fill structure 27b may include a first gap fill pattern 21b surrounding a sidewall of the second gap fill pattern 24b within the opening 15. The modified semiconductor pattern 30b may be formed to surround a sidewall of the modified gap fill structure 27b and a sidewall of the pad pattern 18, but may not be interposed between the gap fill structure 27b and the substrate 1. That is, a surface or inside of the substrate 1 or the impurity region 3 may be partially exposed to be in direct contact with the gap fill structure 27b.

FIG. 6 illustrates a vertical cross-sectional view of a semiconductor device according to yet another exemplary embodiment. As illustrated in FIG. 6, the gap fill structure 27 described with reference to FIG. 2 may be modified to a gap fill structure 27c. The modified gap fill structure 27c may include a first gap fill pattern 21c whose top surface has a middle part concavely recessed. For example, the top surface may have an outer rim near a top of the opening 15 and a lowest most part near a middle or lower region of the opening 15. A second gap fill pattern 24c may be interposed between the first gap fill pattern 21c and the pad pattern 18. That is, a part of the first gap fill pattern 21c may horizontally overlap a conductive pattern 6f disposed at the uppermost part of the conductive patterns 6. The first gap fill pattern 21c may not overlap interlayer insulating pattern 9f disposed at the uppermost part of the interlayer insulating patterns 9, and the first gap fill pattern 21c may be spaced apart from the pad pattern 18 by the second gap fill pattern 24c. Further, the middle part of the top surface of the first gap fill pattern 21c may be recessed up to the lower region of the opening 15.

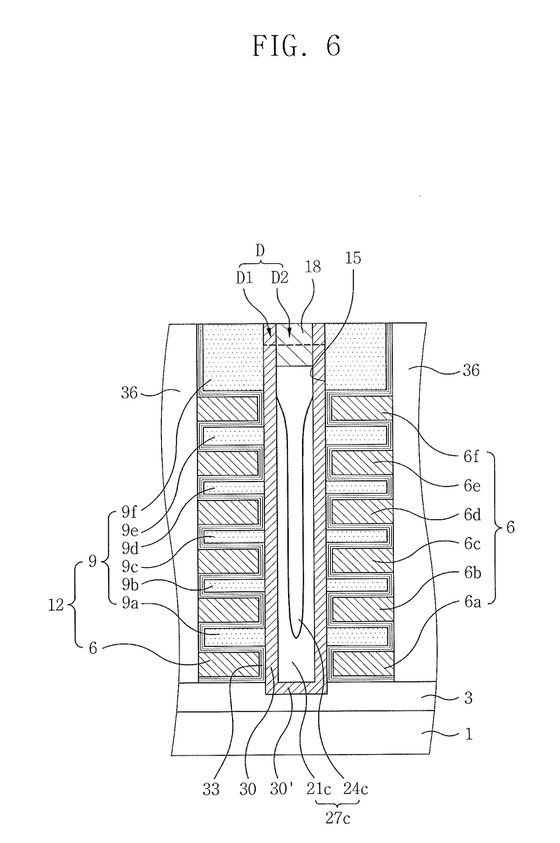

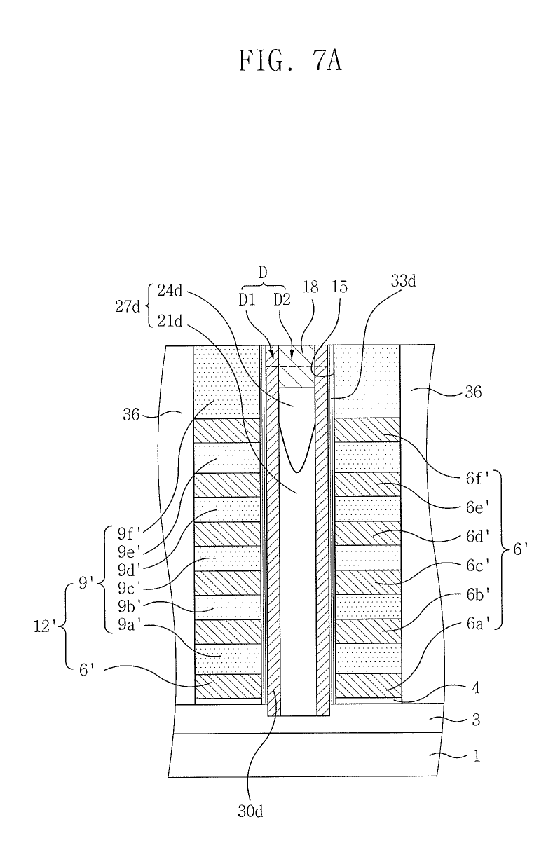

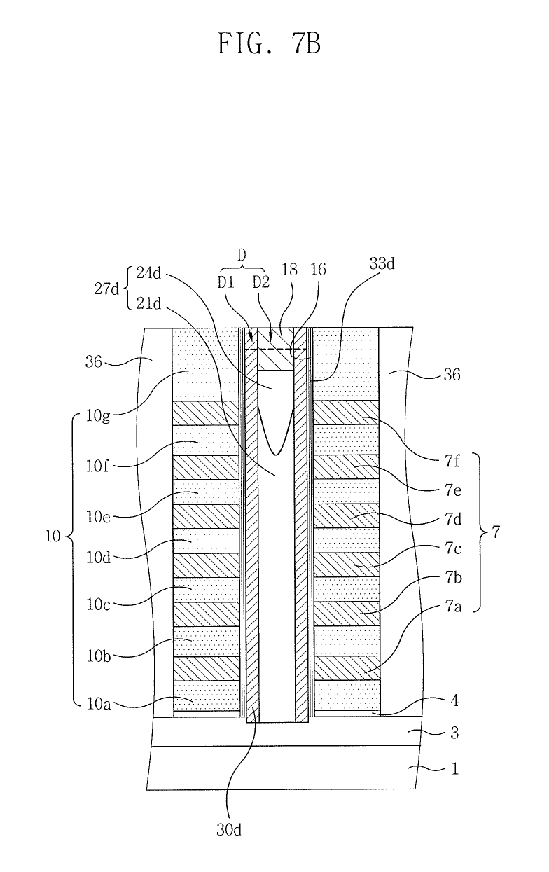

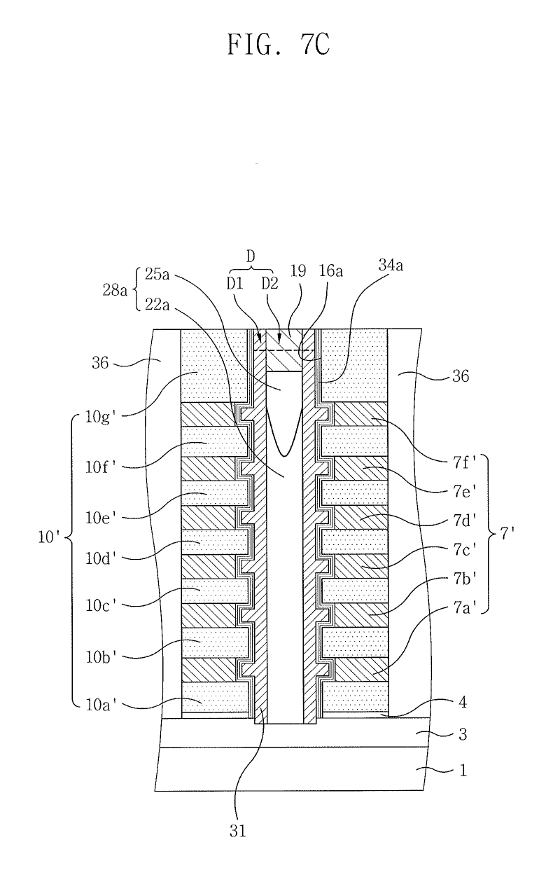

FIG. 7A illustrates a vertical cross-sectional view of a semiconductor device according to yet another exemplary embodiment. As illustrated in FIG. 7A, as described with reference to FIG. 2A, the impurity region 3 may be provided in a substrate 1. Horizontal patterns 12′ may be provided on the substrate 1. A buffer insulating layer 4 may be provided between the horizontal patterns 12′ and the substrate 1. The buffer insulating layer 4 may be formed of an insulating material, e.g., silicon oxide, silicon nitride, or silicon oxynitride.

The horizontal patterns 12′ may include conductive patterns 6a′ to 6f′ and interlayer insulating patterns 9a′ to 9f′. The conductive patterns 6a′ to 6f′ may be defined as a conductive structure 6′, and the interlayer insulating patterns 9a′ to 9f′ may be defined as an interlayer insulating structure 9′. The conductive patterns 6a′ to 6f′ may be spaced apart from each other by the interlayer insulating patterns 9a′ to 9f′ to form a stacked structure. The buffer insulating layer 4 may be provided directly between the impurity region 3 and the conductive pattern 6a′.

The conductive patterns 6a′ to 6f′ may be vertically arranged with sidewalls of the interlayer insulating patterns 9a′ to 9f′, according to an exemplary embodiment. As described with reference to FIG. 2, one or more openings 15 may penetrate the horizontal patterns 12′ and expose a predetermined region of the substrate 1 may be provided. The pad pattern 18 may be provided in an upper region of the opening 15. The pad pattern 18 may be formed of, e.g., polysilicon.

An insulating gap fill structure 27d, which may be similar to the insulating gap fill structure 27 described with reference to FIG. 2, may be formed between the pad pattern 18 and the substrate 1. The insulating gap fill structure 27d may include a first gap fill pattern 21d and a second gap fill pattern 24d. The first and second gap fill patterns 21d and 24d may have various structures that fill the openings 15, e.g., in accordance with the exemplary embodiments discussed above. For example, in exemplary embodiments, the gap fill structure 27d may be modified to have structures similar to that of the gap fill structures 27a, 27b, 27c described with reference to FIGS. 4-6, respectively.

A semiconductor pattern 30d surrounding the gap fill structure 27d and a sidewall of the pad pattern 18 may be provided, e.g., as illustrated in FIG. 7A. The semiconductor pattern 30d may have various structures, e.g., in accordance with the exemplary embodiments discussed above. For example, the semiconductor pattern 30d may be modified to include a bottom part of the semiconductor pattern, which may extend from the semiconductor pattern 30d and is interposed between the gap fill structure 27d and the substrate 1, e.g., in the same manner as the semiconductor pattern 30 illustrated in FIG. 2. As such, the semiconductor pattern 30d may directly extend on the substrate 1 or the impurity region 3.

A gate insulating layer 33d may be interposed between the semiconductor pattern 30d and the horizontal patterns 12′. The gate insulating layer 33d may include a tunnel insulating layer, a data storage layer, and a blocking insulating layer, e.g., as illustrated in FIG. 2. The tunnel insulating layer may be adjacent to the semiconductor pattern 30d, the blocking insulating layer may be adjacent to the horizontal patterns 12′, and the data storage layer may be interposed between the tunnel insulating layer and the blocking insulating layer.

The horizontal patterns 12′ may be defined by a gate isolation insulating layer 36′. That is, the gate isolation insulating layer 36′ may be formed to surround outer sidewalls of the horizontal patterns 12′.

FIG. 7B illustrates a vertical cross-sectional view of a semiconductor device according to yet another exemplary embodiment. Referring to FIG. 7B, a substrate 1 having an impurity region 3 may be provided, e.g., similar to as illustrated in FIG. 2. Structures 7 and 10, which together form horizontal patterns, may be provided on the substrate 1. The structures 7 and 10 may include conductive patterns 7a to 7f and interlayer insulating patterns 10a to 10g. The conductive patterns 7a to 7f may be defined as a conductive structure 7. The interlayer insulating patterns 10a to 10g may be defined as an interlayer insulating structure 10. The conductive patterns 7a to 7f may be spaced apart from each other by the interlayer insulating patterns 10a to 10g to form a stacked structure. A lowermost insulating pattern 10a of the interlayer insulating patterns 10a to 10g may be disposed adjacent to a lower part of the lowermost conductive pattern 7a of the conductive patterns 7a to 7f. An opening 16 defined by sidewalls of the conductive structure 7 and the insulating structure 10 may be provided. The sidewalls of the structures 7 and 10 defining the opening 16 may be vertically arranged with respect to the substrate 1, e.g., the sidewalls of the structures 7 and 10 may be vertically aligned to define the opening 16.

A semiconductor pattern 30d, a gate insulating layer 33d, a gap fill structure 27d, and a pad pattern 18 may be provided in the opening 16, e.g., as illustrated in FIG. 7B. The gap fill structure 27d may have various shapes to fill the openings 16, e.g., the gap fill structure 27d may have a structure similar to the gap fill structures 27a, 27b, and 27c of FIGS. 4-6, respectively. The semiconductor pattern 30d may be modified to a semiconductor pattern 30 having a bottom part 30′, e.g., as illustrated in FIG. 2.

FIG. 7C illustrates a vertical cross-sectional view of a semiconductor device according to yet another exemplary embodiment. Referring to FIG. 7C, a substrate 1 having an impurity region 3 may be provided, e.g., as illustrated in FIG. 2. Structures 7′ and 10′, which together form horizontal patterns, may be provided on the substrate 1. The structures 7′ and 10′ may include conductive patterns 7a′ to 7f′ and interlayer insulating patterns 10a′ to 10g′. The conductive patterns 7a′ to 7f′ may be defined as a conductive structure 7′. The interlayer insulating patterns 10a′ to 10g′ may be defined as an interlayer insulating structure 10′. An opening 16a defined by sidewalls of the structures 7′ and 10′ may be provided.

The sidewalls of the conductive structure 7′ and insulating structure 10′ defining the opening 16a may not be vertically arranged, e.g., the sidewalls may not be vertically aligned to define the opening 16a. For example, a sidewall of the conductive structure 7′ defining the opening 16a may not be vertically arranged with a sidewall of the adjacent patterns of the interlayer insulating structure 10′. In the opening 16a, the distance between the sidewalls of the horizontally facing conductive patterns 7a′ to 7f′ may be greater than a distance between sidewalls of the horizontally facing interlayer insulating patterns 10a′ to 10g′. The sidewalls of the conductive structure 7′ may vertically overlap the sidewalls of the interlayer insulating structure 10′, and the sidewalls of the interlayer insulating structure 10′ may not vertically overlap the sidewalls of the conductive structure 7′. Therefore, in the structures 7′ and 10′, the sidewall of the conductive structure 7′ may be recessed laterally to define an undercut region.

As illustrated in FIG. 7C, the sidewalls of horizontal patterns formed by the structures 7′ and 10′ and that define the opening 16a are not vertically arranged, and thus a sidewall of the semiconductor pattern 31 adjacent to the sidewalls of the horizontal patterns 7′ and 10′ may not be vertical. A gate insulating layer 34a may be provided between the semiconductor pattern 31 and the horizontal patterns 7′ and 10′. As shown in FIG. 2, the gate insulating layer 34a may include a tunnel insulating layer, a data storage layer, and a blocking insulating layer. The gate insulating layer 34a may be formed in the undercut region of the conductive structure 7′.

The semiconductor pattern 31 may be formed on the sidewall of the opening 16a. However, embodiments are not limited hereto. For example, the semiconductor pattern 31 may include a bottom part of the semiconductor pattern that extends from the semiconductor pattern 31 and is interposed between the gap fill structure 28a and the substrate 1, e.g., in the same manner as the semiconductor pattern 30 illustrated in FIG. 2. The semiconductor pattern 31 may be formed in the undercut region of the conductive structure 7′. For example, both the insulating layer 34a and the semiconductor pattern 31 may be formed in the undercut region of the conductive structure 7′.

A pad pattern 19 may be provided in an upper region of the opening 16a, e.g., as illustrated in FIG. 7C. An insulating gap fill structure 28a formed between the pad pattern 19 and the substrate 1 and including first and second gap fill patterns 22a and 25a may be provide, e.g., as illustrated in FIG. 2. However, the insulating gap fill structure 28a may have various structures. For example, in another embodiment, the gap fill structure 28a may be modified to have structures similar to the gap fill structures 27a, 27b, and 27c of FIGS. 4-6, respectively.

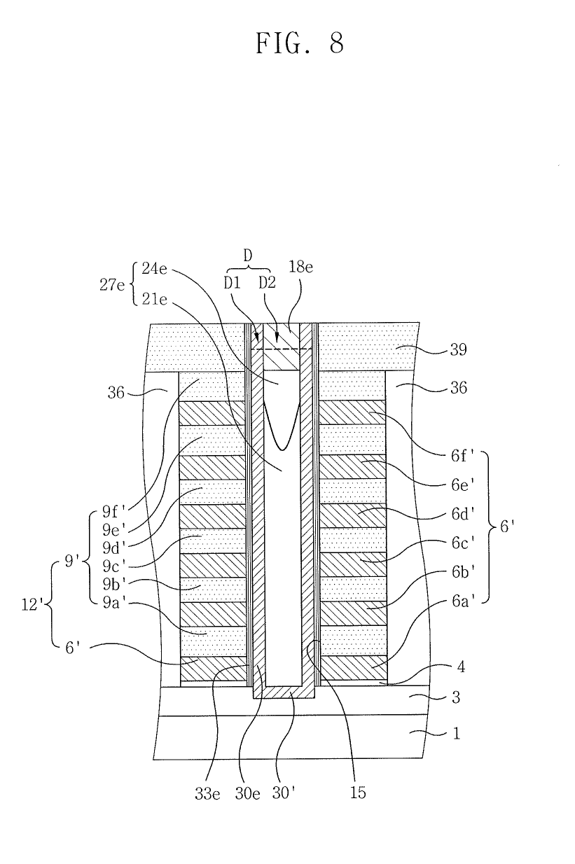

FIG. 8 illustrates a vertical cross-sectional view of a semiconductor device according to yet another exemplary embodiment. Referring to FIG. 8, as described with reference to FIG. 2, an impurity region 3 may be provided in a substrate 1. As described with reference to FIG. 7A, horizontal patterns 12′ may be provided on the substrate 1, and a buffer insulating layer 4 may be provided between the horizontal patterns 12′ and the substrate 1.

The horizontal patterns 12′ may include conductive patterns 6a′ to 6f′ and interlayer insulating patterns 9a′ to 9f′, e.g., as illustrated in FIG. 8. The conductive patterns 6a′ to 6f′ may be defined as a conductive structure 6′, and the interlayer insulating patterns 9a′ to 9f′ may be defined as an interlayer insulating structure 9′.

A gate isolation insulating layer 36 surrounding outer sidewalls of the horizontal patterns 12′ may be provided. The gate isolation insulating layer 36 may be formed of an insulating material, e.g., silicon oxide.

A capping insulating pattern 39 may cover the horizontal patterns 12′ and the gate isolation insulating layer 36. The capping insulating pattern 39 may have a greater planar area and width than the horizontal patterns 12′. The capping insulating pattern 39 may be formed of an insulating material, e.g., silicon oxide, silicon nitride, and/or silicon oxynitride.

One or more openings 15′ may be formed that penetrate the capping insulating pattern 39 and the horizontal patterns 12′. A pad pattern 18e may be provided in an upper region of the opening 15′. The pad pattern 18e may include, e.g., polysilicon. As illustrated in FIG. 2, an insulating gap fill structure 27e formed between the pad pattern 18e and the substrate 1 and including first and second gap fill patterns 21e and 24e may be provided. In other embodiments, the gap fill structure 27e may be modified to the modified gap fill structures 27a, 27b, and 27c of FIGS. 4-6, respectively.

A semiconductor pattern 30e may be formed to surrounding a sidewall of the gap fill structure 27e and a sidewall of the pad pattern 18e. A bottom part 30e′ of the semiconductor pattern, which extends from the semiconductor pattern 30e and is interposed between the gap fill structure 27e and the substrate 1, may be provided. The semiconductor pattern 30e and the bottom part 30′ of the semiconductor pattern may be formed as, e.g., a serially connected layer and/or continuous layer. In other embodiments, the bottom parts 30′ may be omitted.

A gate insulating layer 33e interposed between the semiconductor pattern 30e and the horizontal patterns 12′ may be provided. The gate insulating layer 33e may include a tunnel insulating layer, a data storage layer, and a blocking insulating layer, e.g., as illustrated in FIG. 2. A surface or inside of the substrate 1 or the impurity region 3 may or may not be partially exposed to be in direct contact with the gap fill structure 27e.

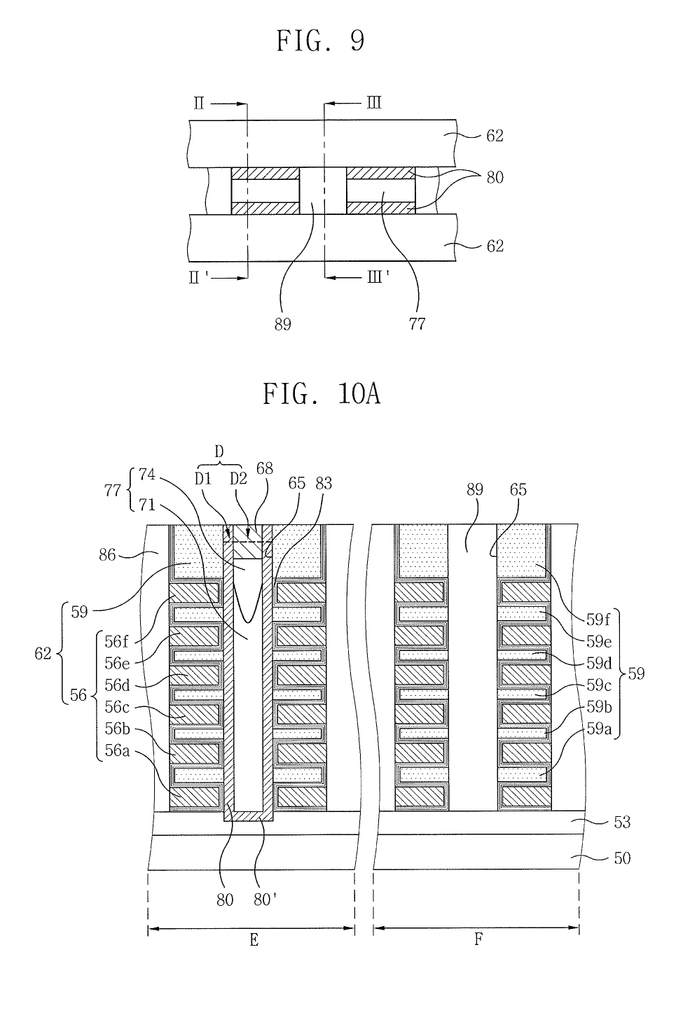

A semiconductor device according to yet another exemplary embodiment will be described below with reference to FIGS. 9, 10A, and 10B. In FIGS. 10A and 10B, a part represented by “E” is a region taken along line II-II′ of FIG. 9, and a part represented by “F” is a region taken along line III-III′ of FIG. 9.

Referring to FIGS. 9 and 10A, an impurity region 53 may be provided in a substrate 50 formed of, e.g., a semiconductor material as illustrated in FIG. 2. Horizontal patterns 62 may be provided on the substrate 50. The horizontal patterns 62 may include conductive patterns 56a to 56f and interlayer insulating patterns 59a to 59f. The conductive patterns 56a to 56f may be defined as a conductive structure 56. The interlayer insulating patterns 59a to 59f may be defined as an interlayer insulating structure 59. The conductive patterns 56a to 56f may be spaced apart from each other by the interlayer insulating patterns 59a to 59f to form a stacked structure. Further, the conductive patterns 56a to 56f may be interposed between, e.g., alternately arranged with respect to, the interlayer insulating patterns 59a to 59f,

One or more openings 65 may penetrate the horizontal patterns 62 and expose a predetermined region of the substrate 50. The opening 65 may be in the shape of a line, e.g., when viewed from a plan view as illustrated in FIG. 9. Therefore, the horizontal patterns 62 may be in the shape of lines spaced apart from each other. For example, the horizontal patterns 62 may be arranged on lines shapes arranged in parallel to each other, e.g., as illustrated in FIG. 9. Sidewalls of the conductive pattern 56 in the opening 65 may not be vertically arranged, e.g., vertically aligned, with sidewalls of the insulating pattern 59.

Insulating pillars 89 spaced apart from each other may be provided in the openings 65. The insulating pillars 89 may be formed of an insulating material, e.g., silicon oxide, silicon nitride, or silicon oxynitride.

A gap fill structure 77 may be provided in the opening 65 between the insulating pillars 89. The gap fill structure 77 may include first and second gap fill patterns 71 and 77. When viewed from a vertical cross-sectional view, the gap fill structure 77 may be in substantially the same shape as the gap fill structure 27 of FIG. 2. In the same manner as the gap fill structure 27 of FIG. 2, the gap fill structure 77 may be modified to, e.g., the gap fill structure 27a of FIG. 4, the gap fill structure 27b of FIG. 5, and the gap fill structure 27c of FIG. 6.

A pad pattern 68 may be provided in an upper part of the gap fill structure 77 between the insulating pillars 89. For example, the pad pattern 68 may be formed at the upper part of the gap fill structure 77 and may be disposed between the insulating pillars 89. The pad pattern 68 may be formed of, e.g., polysilicon.

A semiconductor pattern 80 may be interposed between a sidewall of the pad pattern 68 and sidewalls of the horizontal patterns 62, and may be interposed between a sidewall of the gap fill structure 77 and the sidewalls of the horizontal patterns 62. The semiconductor pattern 80 may be formed of, e.g., crystalline silicon. For example, the semiconductor pattern 80 may be formed of polysilicon.

A bottom part 80′ of the semiconductor pattern, which may extend from the semiconductor pattern 80, may be interposed between the gap fill structure 77 and the substrate 50. In other embodiments, the bottom part 80′ of the semiconductor pattern may be omitted.

A gate insulating layer 83 may be provided between the semiconductor pattern 80 and the conductive patterns 56. The gate insulating layer 83 may include a tunnel insulating layer, a data storage layer, and a blocking insulating layer, e.g., as illustrated in FIG. 2.

The gate insulating layer 83 may be interposed between the semiconductor pattern 80 and the conductive patterns 56. The gate insulating layer 83 may extend between the conductive patterns 56 and the insulating patterns 59. Further, the gate insulating layer 83 may be interposed between a lowermost conductive pattern 56a of the conductive patterns 56 and the substrate 50.

A gate isolation insulating layer 89 may surround outer sidewalls of the horizontal patterns 62. The gate isolation insulating layer 89 may be formed of, e.g., an insulating material such as silicon oxide.

In other embodiment, the conductive patterns 56 defining the opening 65 and the interlayer insulating patterns 59 may be modified as illustrated in FIG. 10B. As illustrated in FIG. 10B, sidewalls of the modified conductive patterns 56′ may define the opening 65 and sidewalls of the modified interlayer insulating patterns 59′ may be vertically arranged, e.g., aligned, with the modified conductive patterns 56′. The gate insulating layer 83 may be modified not to extend between the modified conductive patterns 56′ and the modified interlayer insulating patterns 59′. For example, the gate insulating layer 83 may be interposed between sidewalls of the modified conductive patterns 56′ and interlayer insulating patterns 59′ defining the opening 65 and the semiconductor pattern 80.

Methods of fabricating a semiconductor device according to exemplary embodiments will be described below.

FIG. 11 illustrates a plan view of a semiconductor device fabricated according to exemplary embodiments discussed below. FIGS. 12A to 12K illustrates vertical cross-sectional views of stages in a method of fabricating a semiconductor device, according to the exemplary embodiment.

Referring to FIG. 12A, a substrate 100 may be provided, e.g., a substrate as illustrated in FIG. 2. The substrate 100 may be a semiconductor substrate. The substrate 100 may include a memory cell region (or a cell array region) where memory cells may be formed, and a peripheral circuit region where peripheral circuits for operating the memory cells may be formed. The substrate 100 may be formed of, e.g., a semiconductor material of a single crystalline structure. For example, the substrate 100 may be a P-type silicon wafer.

An impurity region 103 may be provided in the substrate 100, e.g., the impurity region 103 may form the uppermost surface of the substrate 100. The impurity region 103 may be in, e.g., a pocket well structure or a multiple well structure. According to an exemplary embodiment, the impurity region 103 may include an N+ type region, i.e., a high-concentration N-type region defined as a source region of a transistor on its surface region. For example, the impurity region 103 may include a p-type well region and a high-concentration N-type source region in a part of the well region.

Sacrificial layers SC1 to SC6 and interlayer insulating layers 106a to 106f may be alternately formed on the substrate 100 to form a stacked structure. Therefore, the sacrificial layers SC1 to SC6 may constitute a sacrificial layer structure SC in which the sacrificial layers SC1 to SC6 are spaced apart from each other by the interlayer insulating layers 106a to 106f to be stacked. The interlayer insulating layers 106a to 106f, which may be interposed between the sacrificial layers SC1 to SC6, may constitute an interlayer insulating structure 106. Embodiments are not limited thereto, e.g., additional or less sacrificial layers and interlayer insulating layers may be formed on the substrate 100.

The interlayer insulating layers 106a to 106f may be formed of an insulating material, e.g., silicon oxide, silicon oxynitride, and/or silicon nitride. The sacrificial layers SC1 to SC6 may be formed of a material capable of minimally etching the interlayer insulating layers 106a to 106f and selectively removing the interlayer insulating layers 106a to 106f.

The sacrificial layer may be formed earlier than the interlayer insulating layer. For example, as illustrated, a first-formed sacrificial layer SC1 of the sacrificial layers SC1 to SC6 may be formed to be more adjacent to the substrate 100 than a first formed interlayer insulating layer 106a of the interlayer insulating layers 106a to 106f. A last-formed sacrificial layer SC6 of the sacrificial layers SC1 to SC6 may be formed to be covered with a last formed interlayer insulating layer 106f of the interlayer insulating layers 106a to 106f.

In an exemplary embodiment, a buffer layer (not shown) may be formed between the first-formed sacrificial layer SC1 and the substrate 100. The buffer layer may be formed of, e.g., silicon oxide.

Referring to FIGS. 11 and 12B, the interlayer insulating structure 106 and the sacrificial layer structure SC may be patterned to form openings 109. The openings 109 may expose a surface of the substrate 100, the impurity region 103, or the buffer layer. That is, the openings 109 may penetrate the interlayer insulating structure 106 and the sacrificial layer structure SC to expose underlying layers. The openings 109 may be formed in the shape of holes. The openings 109 may form a trench in the impurity region 103 and/or the substrate 100 such that a top surface of the substrate 100 is higher than the surface exposed by the opening 109.

Referring to FIGS. 11 and 12C, a preliminary semiconductor layer may be formed, e.g., conformally formed, to cover the substrate exposed by the openings 109, sidewalls of the openings 109, and a top surface of stacked structure, e.g., the interlayer insulating layers 106f. The preliminary semiconductor layer may be formed not to fill middle parts between the sidewalls of the openings 109. That is, the width of each of the openings 109 may be at least twice that of a width of the preliminary semiconductor layer formed on the sidewalls of the openings 109.

The preliminary semiconductor layer may be formed of, e.g., a material including at least one of silicon and silicon germanium. The preliminary semiconductor layer may be formed using a deposition technique, e.g., using a chemical vapor deposition (CVD) technique or an atomic layer deposition (ALD) technique. For example, the preliminary semiconductor layer may be formed of an amorphous silicon layer.

The preliminary semiconductor layer may be exposed to an annealing process for, e.g., crystallizing the preliminary semiconductor layer. The crystallized preliminary semiconductor layer may form a semiconductor layer 112, e.g., as illustrated in FIG. 12C. The annealing process may be performed at, e.g., a temperature between 500° C. and 1000° C. As such, the preliminary semiconductor layer may be formed as a crystalline semiconductor layer 112 as a result of the annealing process. The semiconductor layer 112 may be formed of a semiconductor material of, e.g., a polycrystalline structure. The semiconductor layer 112 may be formed of, e.g., a polysilicon layer.

An insulating first preliminary gap fill layer may be formed on the substrate to fill, e.g., substantially completely fill, the opening 109. The insulating first preliminary gap fill layer may be disposed in the opening 109 adjacent to the semiconductor layer 112. The first preliminary gap fill layer may be partially etched to form a first gap fill pattern 115 in the opening 109. The first gap fill pattern 115 may be formed to have a top surface whose middle part is concavely recessed.

The first gap fill pattern 115 may be formed of, e.g., an insulating oxide. For example, the formation of the first gap fill pattern 115 may include forming an insulating oxide, e.g., silicon oxide, using a deposition method such as ALD or CVD, and partially etching the insulating oxide to partially fill the openings 109. The insulating oxide may be partially etched using a dry etching method.

In another exemplary embodiment, the first gap fill pattern 115 may be modified, e.g., to the first gap fill pattern 21a as described with reference to FIG. 3. In this case, a first preliminary gap fill layer may be formed on the substrate having the semiconductor layer 112 to a uniform thickness along a sidewall and bottom surface of the opening 109, and not to completely fill the opening 109. The first preliminary gap fill layer may be anisotropically etched to form the first gap fill pattern remaining on the sidewall of the opening 109.

In still another exemplary embodiment, the first gap fill pattern 115 may be modified, e.g., to the first gap fill pattern 21c described with reference to FIG. 6. In this case, a first preliminary gap fill layer may be formed on the substrate having the semiconductor layer 112. The first preliminary gap fill layer may fill the opening 109 and may have a void or seam formed therein. The first preliminary gap fill layer may be anisotropically etched to form a first gap fill pattern modified to the first gap fill pattern 21c described with reference to FIG. 6. The preliminary gap fill layer may be etched deeper by, e.g., etching gas infiltrated via the void or seam in the preliminary gap fill layer, so that a middle part of a top surface of the first gap fill pattern may be recessed up to a middle or lower region of the opening 109.

Alternatively, a first preliminary gap fill layer completely filling a lower region of the opening 109, but not completely filling an upper region of the opening 109 may be formed on the substrate having the semiconductor layer 112. Then, the first preliminary gap fill layer may be anisotropically etched to form a first gap fill pattern modified in the same manner as the first gap fill pattern 21c described with reference to FIG. 6.

Referring to FIGS. 11 and 12D, a second preliminary gap fill layer may be formed on the first gap fill pattern 115. The second preliminary gap fill layer may be an oxide formed in a different manner from the first gap fill pattern 115. For example, the first gap fill pattern 115 may be formed of an oxide using a deposition method such as ALD or CVD, and the second preliminary gap fill layer may be formed of a flowable oxide. The flowable oxide may be formed using a flowable CVD (F-CVD) method or a spin coating method. For example, the flowable oxide may be FCVD oxide or Tonen Silazene (TOSZ).

Then, an annealing process for curing the second preliminary gap fill layer formed of, e.g., flowable oxide, may be performed. The cured second preliminary gap fill layer may have a lower density than the first gap fill pattern 115. The annealing process for curing the second preliminary gap fill layer may be performed at, e.g., a temperature between 500° C. and 1000° C. The temperature of the annealing process for curing the second preliminary gap fill layer may be equal to or may be lower than that for crystallizing the preliminary semiconductor layer. In this regard, characteristics of the semiconductor layer 112 may not be changed due to the annealing process for curing the second preliminary gap fill layer. During the annealing process for curing the preliminary gap fill layer, a change in volume of the first gap fill pattern 115 having a higher density may not be observed or may be insignificant.

While the preliminary gap fill layer is cured, the preliminary gap fill layer may be shrunk. In this case, most of the opening 109 is filled with the first gap fill pattern 115 that exhibits relatively high density and is not influenced during the annealing process for curing the preliminary gap fill layer. Thus deterioration of a resulting device due to, e.g., the shrunken preliminary gap fill layer, may be minimized and/or prevented.

Further, as discussed above, the first gap fill pattern 115 may be modified to the first gap fill patterns 21a, 21b, and 21c of FIG. 4-6, respectively. In this case, since the first gap fill pattern 115 may cover the semiconductor layer 112, which may be used as a channel region, deterioration characteristics of a resultant device, in particular, the deteriorated semiconductor layer 112 resulting from the shrunk preliminary gap fill layer, may be minimized and/or prevented.

The cured second preliminary gap fill layer may be planarized until the semiconductor layer 112 on the interlayer insulating layers 106a to 106f is exposed to form a second gap fill layer 118. Therefore, the second gap fill layer 118 may be formed of an oxide having an etch selectivity with respect to the first gap fill pattern 115. The second gap fill layer 118 may be formed of an oxide having a higher etching rate with respect to an oxide etchant than the first gap fill pattern 115. For example, the second gap fill layer 118 may be formed of an oxide having an etching rate about 10 times higher than the first gap fill pattern 115 with respect to a wet etching solution containing hydrofluoric acid (HF).

Both the first and second gap fill patterns 115 and 118 may include silicon (Si) and oxygen (O), and they may include different elements from each other. For example, the first gap fill pattern 115 may include at least one of hydrogen (H) and chlorine (Cl), and the second gap fill layer 118 may include at least one of nitrogen (N), H, and carbon (C). The first gap fill pattern 115 may be formed of, e.g., silicon oxide (Si—H—Cl—O) containing H and Cl, and the second gap fill layer 118 may be formed of, e.g., silicon oxide (Si—N—H—C—O or Si—N—H—O) containing at least one of N, H, and C.

Referring to FIGS. 11 and 12E, the second gap fill layer 118 may be partially etched to form a second gap fill pattern 119. The first and second gap fill patterns 115 and 119 may constitute a gap fill structure 121. An isotropical or anisotropical process may be performed on the second gap fill layer 118 to partially etch the second gap fill layer 118.

According to an exemplary embodiment, the first gap fill pattern 115 formed of an oxide by an ALD technique may be formed at a lower part of the second gap fill pattern 119, and the second gap fill pattern 119 formed on the first gap fill pattern 115 may be minimally shrunk while it is cured by an annealing process. Thus, the formation of a defect such as a void in the gap fill structure 121 may be minimized and/or prevented.

The second gap fill layer 118 may be partially etched using, e.g., a wet etching process that reducing the possibility of and/or does not cause etching damage to the semiconductor layer 112. For example, when the second gap fill layer 118 is formed of F-CVD oxide or TOSZ, the second gap fill layer 118 may be etched using an etching solution containing HF. However, embodiments are not limited thereto, e.g., embodiments are not intended to exclude a dry anisotropic etching process.

As a result of partially etching the second gap fill layer 118, a surface of the semiconductor layer 112 may be partially exposed, e.g., a surface of the semiconductor layer 112 on an uppermost portion of the sidewalls of the opening 109 may be exposed. Since the second gap fill layer 118 is formed of an oxide that is more easily etched than the first gap fill pattern 115, substantially no oxide may remains on the surface of the semiconductor layer 112 exposed as a result of the partial etching of the second gap fill layer 118.

Further, since substantially no oxide may remain on the surface of the semiconductor layer 112 exposed as a result of the partial etching of the second gap fill layer 118, over-etching may be minimized and/or not performed. That is, etching of the second gap fill layer 118 may be easily controlled, and thus distribution characteristics may be enhanced.

Referring to FIGS. 11 and 12F, a pad layer may be formed on the substrate having the second gap fill pattern 119. The pad layer may be formed to fill the remaining part of the opening 109 and to cover the interlayer insulating structure 106. The pad layer may be planarized until an uppermost interlayer insulating layer 106f of the interlayer insulating layers 106a to 106f is exposed. As a result, a pad pattern 124 may be formed, e.g., the pad pattern 124 may be substantially co-planar with an upper surface of the uppermost interlayer insulating layer 106f. The pad pattern 124 may fill the remaining part of the opening 109 and may be formed on, e.g., directly on, the second gap fill pattern 119.

The semiconductor layer 112 may remain in the opening 109 to be formed as a semiconductor pattern 112a, e.g., as illustrated in FIG. 12F. That is, the semiconductor pattern 112a may be formed to surround a sidewall of the gap fill structure 121 and a sidewall of the pad pattern 124. The semiconductor pattern 112a may be formed to cover a bottom surface of the gap fill structure 121. The planarization may be performed using, e.g., a CMP and/or etch-back technique. The pad pattern 124 may be formed of, e.g., crystalline silicon. For example, the pad pattern 124 may be formed of a polysilicon layer.

Referring to FIGS. 11 and 12G, the interlayer insulating structure 106 and the sacrificial layer structure SC may be patterned to form a preliminary gate isolation region 127 exposing the substrate 100 or a top surface of the buffer layer (not shown) between the openings 109. The preliminary gate isolation region 127 may be formed between the adjacent semiconductor patterns 112a. As a result, sidewalls of the interlayer insulating structure 106 and the sacrificial layer structure SC may be exposed by the preliminary gate isolation region 127.

Referring to FIGS. 11 and 12H, the sacrificial layers SC1 to SC6 exposed by the preliminary gate isolation region 127 may be removed. As a result, an empty space exposing a sidewall of the semiconductor pattern 112a, e.g., gate regions may be formed between the interlayer insulating layers 106a to 106f.

The sacrificial layers SC1 to SC6 may be formed of a material such that the substrate 100, the semiconductor pattern 112a, and the pad pattern 124 are minimally etched. Thus, the sacrificial layers SC1 to SC6 may be selectively removed with respect to the substrate 100, the semiconductor pattern 112a and the pad pattern 124. For example, the sacrificial layers SC1 to SC6 may be formed of silicon nitride, the substrate 100 and the semiconductor pattern 112a may be formed of crystalline silicon, and the pad pattern 124 may be formed of polysilicon. Therefore, the sacrificial layers SC1 to SC6 may be selectively removed by an isotropical etching process.

A gate insulating layer 130 may be formed on the substrate from which the sacrificial layers SC1 to SC6 are removed. The gate insulating layer 130 may include a tunnel insulating layer, a data storage layer, and a blocking insulating layer as illustrated in FIG. 2. The tunnel insulating layer may be formed to cover the sidewall of the semiconductor pattern 112a exposed by the empty space formed as a result of removing the sacrificial layers SC1 to SC6. The data storage layer and the blocking insulating layer may be formed to cover, e.g., conformally cover, the tunnel insulating layer.

A conductive layer 133 may be formed to fill the empty space formed as a result of removing the sacrificial layers SC1 to SC6 and as a result of forming the gate insulating layer 130. The preliminary gate isolation region 127 may be formed on the results where the gate insulating layer 130 is formed. The conductive layer 133 may be formed of, e.g., at least one of a conductive doped polysilicon layer, a metal nitride layer, and a metal layer. The conductive layer 133 may be formed using thin film formation techniques exhibiting superior step coverage, e.g., one of CVD and ALD techniques.

Referring to FIGS. 11 and 12I, the conductive layer 133 may be anisotropically etched to form a gate isolation region 127′. The conductive layer 133 may remain in the empty space formed as a result of removing the sacrificial layers SC1 to SC6 to form conductive patterns 134a to 134f. The conductive patterns 134a to 134f may be defined as a conductive structure 134. Meanwhile, the interlayer insulating layers 106a to 106f may be defined as interlayer insulating patterns 106a′ to 106f′. As such the conductive patterns 134a to 134f and the interlayer insulating patterns 106a′ to 106f′ may be alternately stacked, e.g., as illustrated in FIG. 12I.

For example, the conductive patterns 134a to 134f may be spaced apart from each other by the interlayer insulating patterns 106a′ to 106f′ to be stacked. Further, the conductive patterns 134a to 134f may be interposed between the interlayer insulating patterns 106a′ to 106f′. According to an exemplary embodiment, an interlayer insulating structure 106′ formed of the interlayer insulating patterns 106a′ to 106f′ and the conductive structure 134 formed of the conductive patterns 134a to 134f may be defined as horizontal patterns 135. Therefore, the horizontal patterns 135 may include the conductive patterns 134a to 134f vertical to a top surface of the substrate 100 and the interlayer insulating patterns 106a′ to 106f′.

Referring to FIGS. 11 and 12J, a gate isolation insulating layer 136 filling the gate isolation region 127′ may be formed. The gate isolation insulating layer 136 may be formed of an insulating material such as a silicon oxide layer. The formation of the gate isolation insulating layer 136 may include forming an insulating layer on the substrate having the gate isolation region 127′, and planarizing the insulating layer. During the planarization process, the gate insulating layer may be removed from the pad pattern 124 to expose the pad pattern 124.

Impurities may be implanted into the substrate having the semiconductor pattern 112a and the pad pattern 124. As a result, a first impurity region D1 may be formed in the semiconductor pattern 112a adjacent to the pad pattern 124, and a second impurity region D2 may be formed in the pad pattern 124. The first and second impurity regions D1 and D2 may constitute a drain region D of a transistor. The drain region D may be, e.g., a high-concentration N+-type.

Referring to FIG. 12J, while a lower boundary of the drain region D is represented by the dotted line, embodiments of the drain region D are not limited to the boundary represented by the dotted line. For example, in the drain region D, the impurity region may be formed over all regions of the pad pattern 124, and the impurity region may be formed in the semiconductor pattern 112a adjacent to the pad pattern 124. Further, while the drain region D may be formed after the gate isolation insulating layer 136 is formed, embodiments are not limited hereto. For example, the drain region D may be formed immediately after the pad pattern 124 is formed.

Referring to FIG. 12K, an upper interlayer insulating layer 139 may be formed on the substrate having the gate isolation insulating layer 136. The upper interlayer insulating layer 139 may be formed of, e.g., a silicon oxide layer. A bit line plug 142 may be formed penetrating through the upper interlayer insulating layer 139. The bit line plug 142 may be electrically connected to the pad pattern 124. A bit line 145 may be formed, e.g., of a conductive material, on the upper interlayer insulating layer 139. The bit line 145 may be connected to the pad pattern 124 through the bit line plug 142. Embodiments are not limited thereto, e.g., the upper interlayer insulating layer 139 may be omitted, and the bit line 145 may be formed to be electrically connected to the pad pattern 124 without using the bit line plug 142.

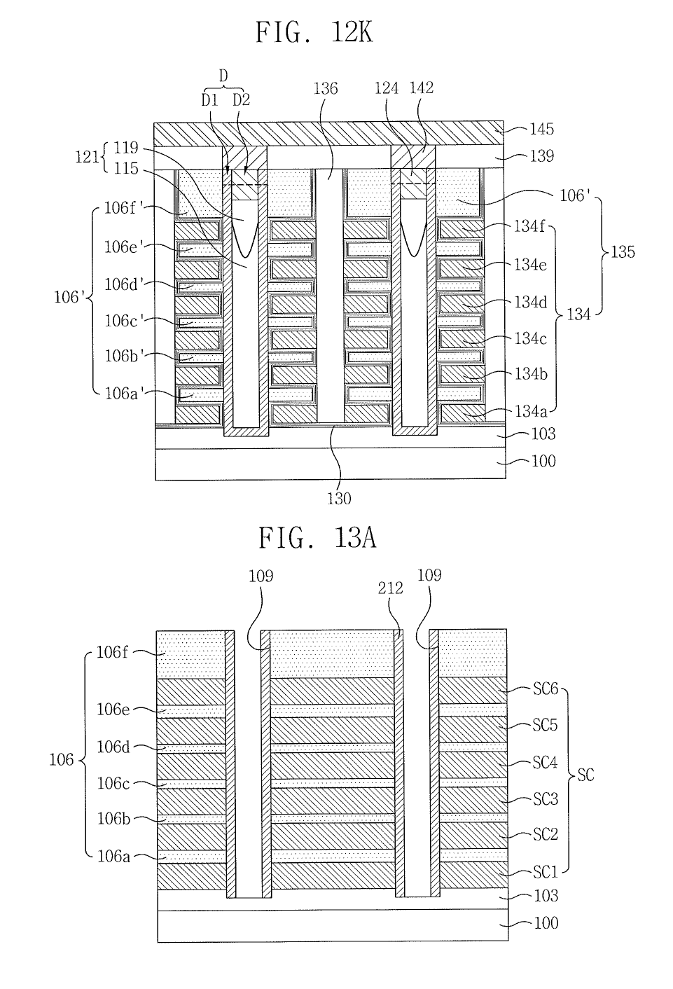

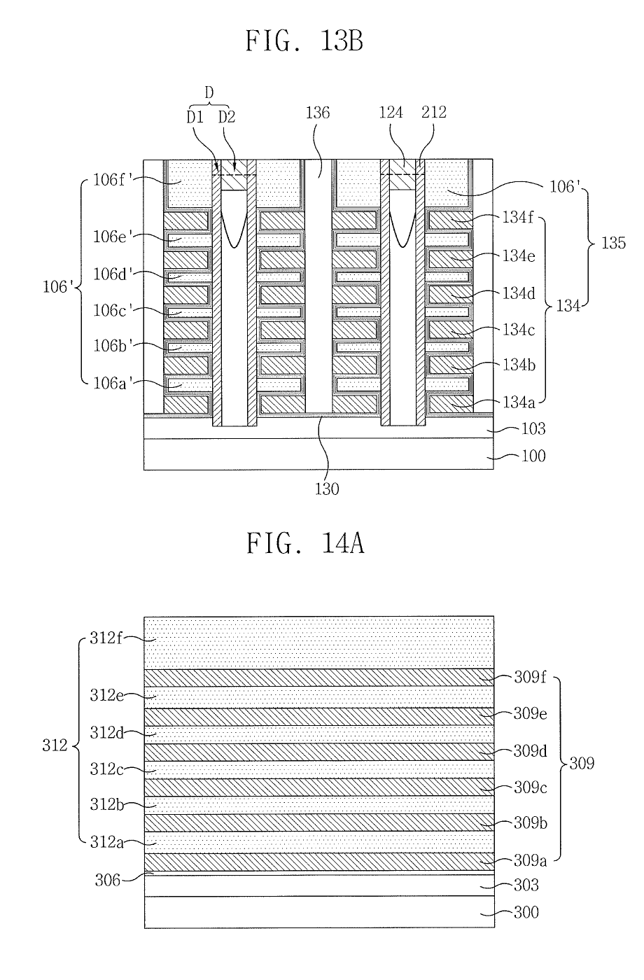

The semiconductor pattern 112a, e.g., as discussed in the stages of fabricating a semiconductor device as discussed above with reference FIGS. 12A to 12K, may be modified. An exemplary modification of the embodiment illustrated in FIGS. 12A to 12K will be described below with reference to FIGS. 13A and 13B.

Referring to FIG. 13A, a substrate on which up to the semiconductor layer 112 described with reference to FIG. 12C is formed may be prepared. Afterwards, before the first gap fill pattern 115 described with reference to FIG. 12D is formed, the semiconductor layer 112 may be anisotropically etched. As a result, a semiconductor pattern 212 remaining on a sidewall of the opening 109 may be formed and other portions may be removed.

Referring to FIG. 13B, a gap fill structure 121 including first and second gap fill patterns 115 and 119 may be formed in the same manner as described in FIGS. 12D to 12E. Further, a pad pattern 124 may be formed in the same manner as described in FIG. 12F. The semiconductor pattern 112a in the embodiment of FIGS. 12A to 12K may surround sidewalls of the gap fill structure 121 and the pad patterns 124, and may cover a bottom surface of the gap fill structure 121. However, a modified semiconductor pattern 212 of FIG. 13B may be formed to surround the sidewalls of the gap fill structure 121 and of the pad patterns 124 without completely covering the bottom surface of the gap fill structure 121. Then, the same process as described in FIGS. 12G to 12J may be performed.

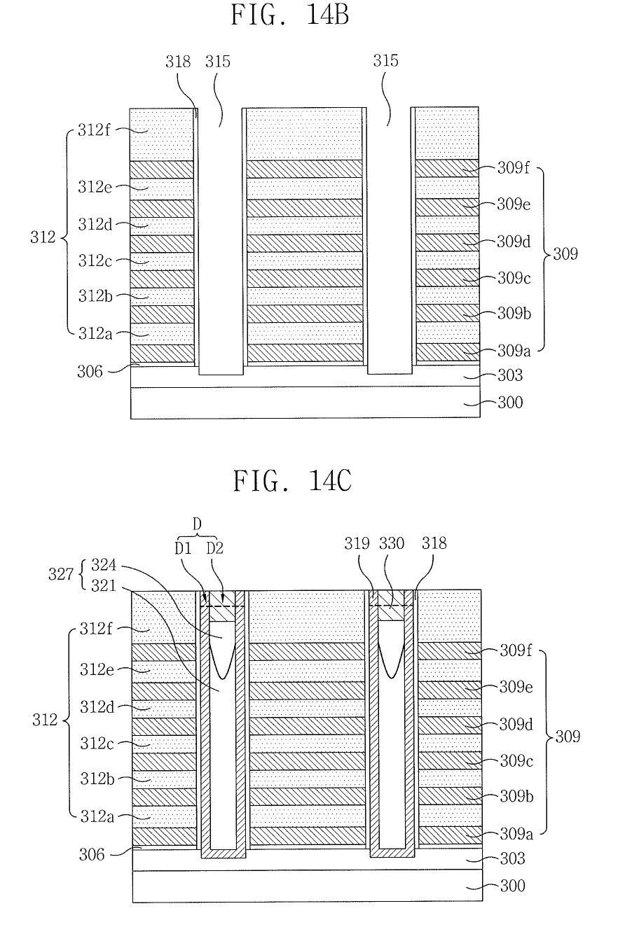

Stages in a method of fabricating a semiconductor device according to still another exemplary embodiment will be described with reference to FIGS. 14A to 14D. Referring to FIG. 14A, a substrate 300 as illustrated in FIG. 12A may be provided. An impurity region 303 may be formed in the substrate 300.

A buffer layer 306 may be formed on the substrate 300. The buffer layer 306 may be an insulating layer formed of at least one of a silicon oxide layer and a high dielectric layer.

Conductive layers 309a to 309f and interlayer insulating layers 312a to 312f may be alternately formed on the buffer layer 306. Therefore, the conductive layers 309a to 309f constituting a conductive layer structure 309 may be spaced apart from each other by the interlayer insulating layers 312a to 312f to be stacked. Further, the interlayer insulating layers 312a to 312f may constitute an interlayer insulating structure 312.

The conductive layers 309a to 309f may be formed of a material such as polysilicon. The interlayer insulating layers 312a to 312f may be formed of an insulating material such as silicon oxide, silicon oxynitride, or silicon nitride. An uppermost interlayer insulating layer 312f of the interlayer insulating layers 312a to 312f may be thicker than each of the remaining interlayer insulating layers 312a to 312e. Such an arrangement may ensure a space in which a pad pattern is to be formed in subsequent stages.

Referring to FIG. 14B, an opening 315 may be formed. The opening 315 may penetrate the conductive layer structure 309 and the interlayer insulating structure 312. The opening 315 may be in the shape of a hole. The opening 315 may expose the substrate 300 or the impurity region 303 formed in the substrate 300.

A gate insulating layer 318 may be formed on a sidewall of the opening 315. Fr example, an insulating material layer may be formed on the substrate having the opening 315, e.g., the insulating material layer may deposited on sidewalls of the opening 315. The insulating material layer may be etched so that the insulating material remains on the sidewall of the opening 315 and exposes the substrate 300 on the bottom surface of the opening 315. As a result, the gate insulating layer 318 may be formed. The gate insulating layer 318 may include a tunnel insulating layer, a data storage layer, and a blocking insulating layer, e.g., as described in FIG. 2.

After the gate insulating layer 318 is formed, the substrate 300 exposed by the opening 315 may be etched to form a recessed region. That is, a bottom region of the opening 315 may be formed to be disposed below a main surface of the substrate 300. As a result, the gate insulating layer 318 may be excluded or substantially excluded along a bottom surface of the opening 315.

Referring to FIG. 14C, processes of forming the semiconductor layer 112 to forming the pad pattern 124 may be performed on the results where the gate insulating layer 318 is formed on sidewalls of the opening 315. In the opening 315, a semiconductor pattern 319, a gap fill structure 327 including first and second gap fill patterns 321 and 324, and a pad pattern 330 corresponding to the semiconductor pattern 112a, the gap fill structure 121 including first and second gap fill patterns 115 and 119, and a pad pattern 124 of FIG. 12F, respectively, may be formed. As described with reference to FIG. 12J, a high-concentration impurity region D may be formed in the pad pattern 330 and in the semiconductor pattern 319.

Referring to FIG. 14D, the conductive layer structure 309 and the interlayer insulating structure 312 may be patterned to form a preliminary gate isolation region 333, which may correspond to the preliminary gate isolation region 127 described in FIG. 12G. Then, a gate isolation insulating layer 336 filling the gate isolation region 333 may be formed. The gate isolation insulating layer 336 may be formed of an insulating layer such as silicon oxide.

Therefore, the conductive layers 309a to 309f and the interlayer insulating layers 312a to 312f may be defined as conductive patterns 309a′ to 309f′ and interlayer insulating patterns 312a′ to 312f′, respectively, by the gate isolation insulating layer 336. The conductive patterns 309a′ to 309f′ may be defined as a gate electrode structure 312′ and the interlayer insulating patterns 312a′ to 312f′ may be defined as an insulating structure 312′. The conductive patterns 309a′ to 309f′ and the interlayer insulating patterns 312a′ to 312f′ may be defined as horizontal patterns 313.

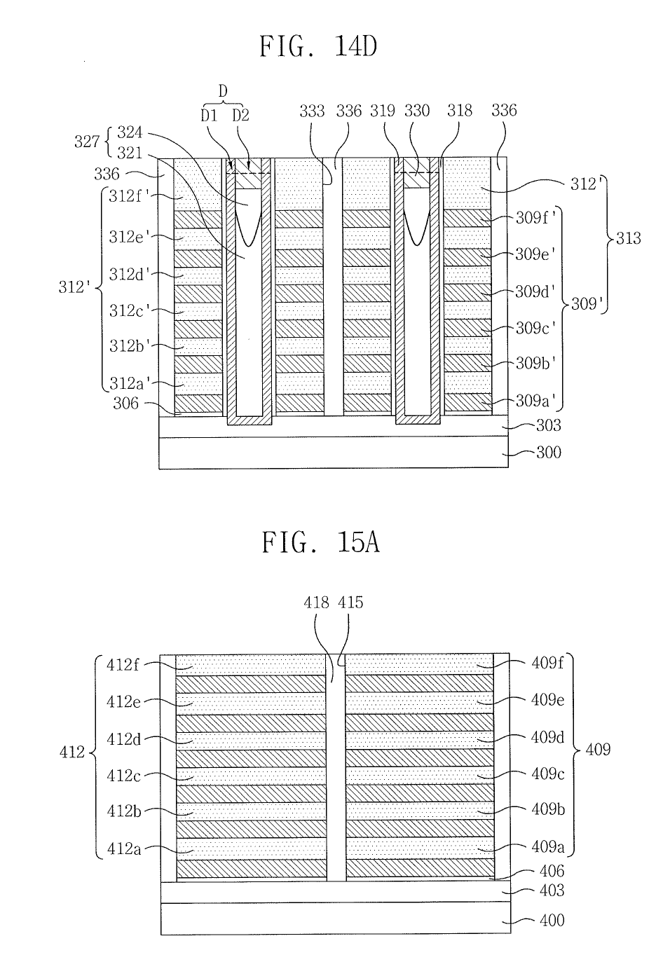

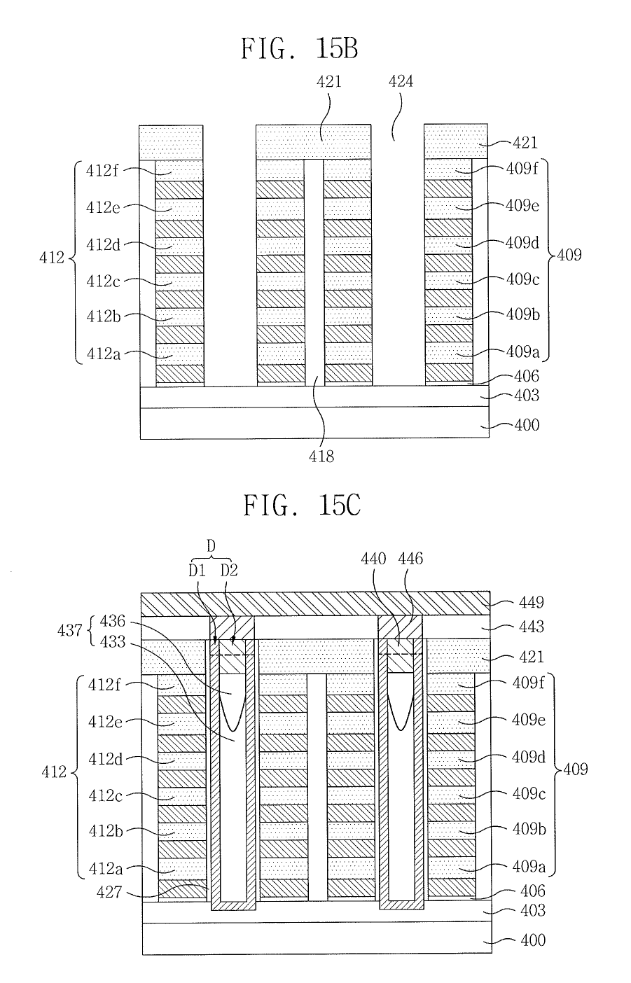

Stages in a method of fabricating a semiconductor device according to yet another exemplary embodiment will be described with reference to FIGS. 15A to 15C.

Referring to FIG. 15A, an impurity region 403 may be formed in the substrate 400, e.g., as described with reference to FIG. 14A. A buffer layer 406 may be formed on the substrate 400. The buffer layer 406 may be an insulating layer formed of, e.g., at least one of a silicon oxide layer and a high dielectric layer.

The conductive layers 409a to 409f and interlayer insulating layers 412a to 412f may be alternately formed on the buffer layer 406, e.g., as illustrated in FIG. 14A. Therefore, the conductive layers 409a to 409f constituting a conductive layer structure 409 may be spaced apart from each other by the interlayer insulating layers 412a to 412f to form a stacked structure. Further, the interlayer insulating layers 412a to 412f may constitute an interlayer insulating structure 412.

The conductive layer structure 409 and the interlayer insulating structure 412 may be patterned to form a gate isolation region 415 corresponding to the preliminary gate isolation region 127 described in FIG. 12G. When viewed from a plan view, the gate isolation region 415 may be in the shape of a line.

A gate isolation insulating layer 418 may be formed to fill the gate isolation region 415. The gate isolation insulating layer 418 may be formed of an insulating layer such as silicon oxide.

A capping insulating layer 421 covering the gate isolation insulating layer 418 and the interlayer insulating structure 412 may be formed on the substrate having the gate isolation insulating layer 418. The capping insulating layer 421 may be formed of an insulating material such as silicon nitride, silicon oxynitride, or silicon oxide.

Referring to FIG. 15B, the capping insulating layer 421, the conductive layer structure 409 and the interlayer insulating structure 412 may be patterned to form an opening 424 corresponding to the opening 315 described in FIG. 14B.

The conductive layers 409a to 409f and the interlayer insulating layers 412a to 412f may be formed as conductive patterns 409a′ to 409f′ and interlayer insulating patterns 412a′ to 412f′, respectively, defined in the shape of a line by the gate isolation insulating layer 418. Further, the opening 424 may vertically penetrate the conductive patterns 409a′ to 409f′ and the interlayer insulating patterns 412a′ to 412f′ to expose the substrate 400.

Referring to FIG. 15C, a gate insulating layer 315 may be formed on a sidewall of the opening 424 as illustrated in FIG. 14B. Afterwards, processes of forming the semiconductor layer 112 to forming the pad pattern 124 may be performed on the results where the gate insulating layer 424 is formed as described in FIGS. 12C to 12F. As a result, a semiconductor pattern 430, a gap fill structure 433 including first and second gap fill patterns 433 and 436, and a pad pattern 440 corresponding to the semiconductor pattern 112a, the gap fill structure 121 including first and second gap fill patterns 115 and 119, and the pad pattern 124 of FIG. 12F, respectively, may be formed in the opening 424.

An upper interlayer insulating layer 443 may be formed on the substrate having the pad pattern 440. The upper interlayer insulating layer 443 may be formed of a silicon oxide layer. A bit line plug 446 penetrating the upper interlayer insulating layer 443 and electrically connected to the pad pattern 440 may be formed. A bit line 449 formed of a conductive material may be formed on the upper interlayer insulating layer 443. The upper interlayer insulating layer 443 may be omitted, and the bit line 449 may be formed to be electrically connected to the pad pattern 440.

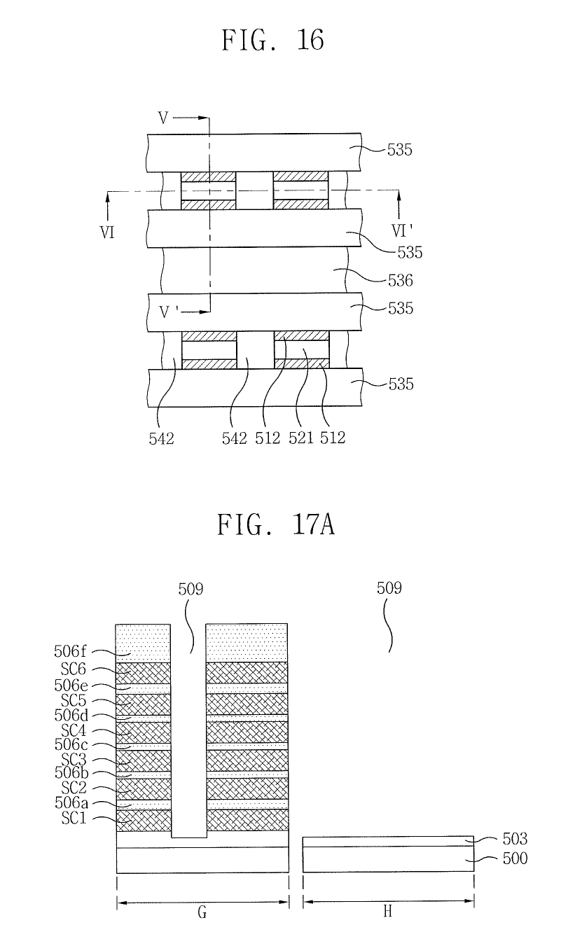

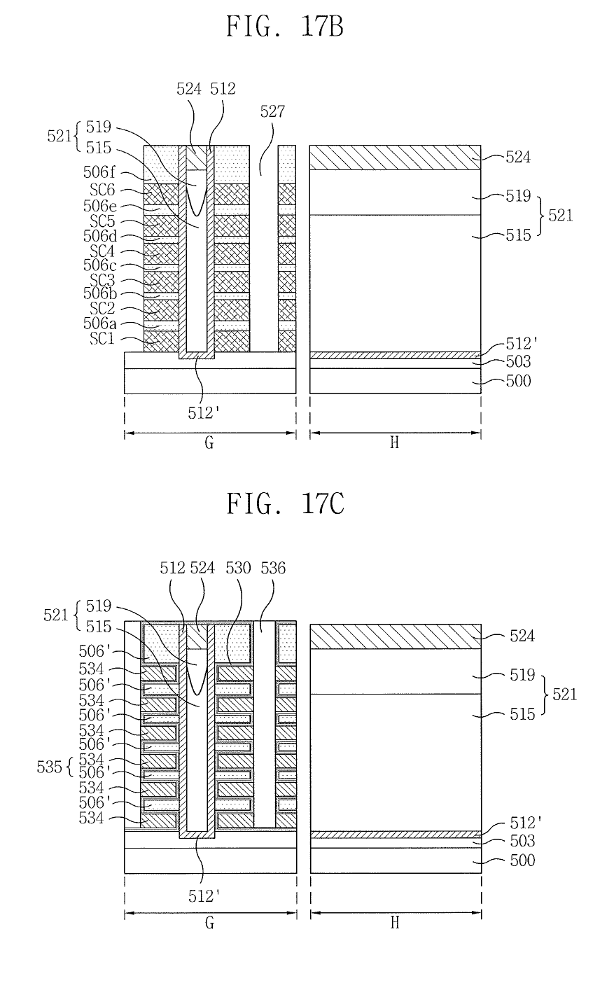

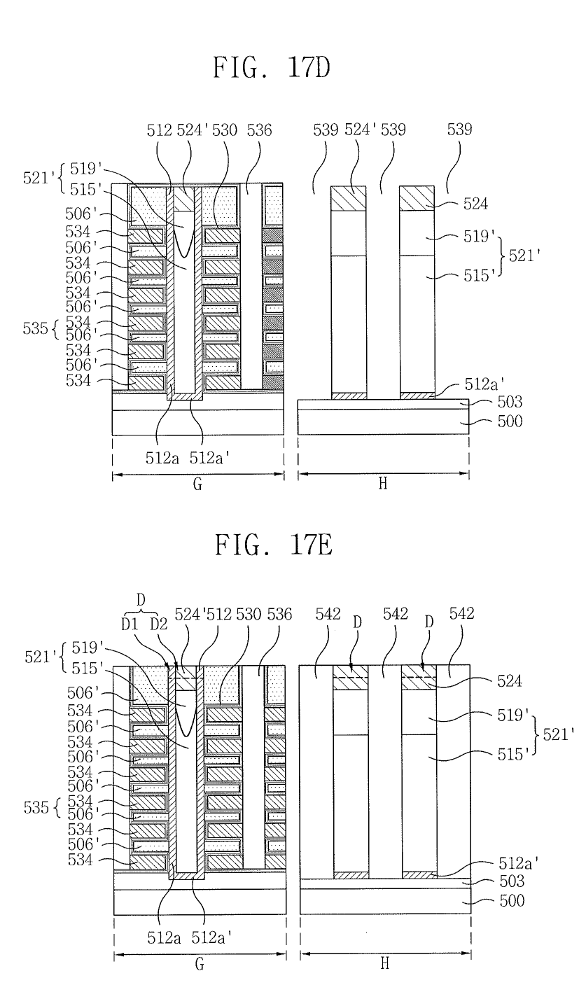

Next, a method of fabricating a semiconductor device according to yet another exemplary embodiment will be described below with reference to FIGS. 16 and 17A to 17E. In FIGS. 17A to 17E, a part represented by “E” is a region taken along line V-V′ of FIG. 16, and a part represented by “H” is a region taken along line VI-VI′ of FIG. 16.

Referring to FIGS. 16 and 17A, an impurity region 503 may be formed in a substrate 500 as illustrated in FIG. 12A. As illustrated in FIG. 12A, sacrificial layers SC1 to SC6 and interlayer insulating layers 506a to 506f may be alternately formed on the substrate 500 to form a stacked structure.

An opening 509 in the shape of, e.g., a line vertically penetrating the interlayer insulating layers 506a to 506f and the sacrificial layers SC1 to SC6 and crossing them, may be formed. While the opening 109 as illustrated in FIG. 12B is in the shape of a hole, the opening 509 in this embodiment may be in the shape of a line.

Referring to FIGS. 16 and 17B, a semiconductor layer 512 may be formed on the substrate having the opening 509. The semiconductor layer 512 may be formed of, e.g., a crystalline silicon layer. For example, the semiconductor layer 512 may be formed of a polysilicon layer.

A substantially similar process as that for forming the first and second gap fill patterns 115 and 119 of FIGS. 12D to 12E may be performed to form a first preliminary gap fill pattern 515 partially filling the opening 509 on the semiconductor layer 512, and to form a second preliminary gap fill pattern 519 on the first preliminary gap fill pattern 515. The first and second preliminary gap fill patterns 515 and 519 may be defined as a preliminary gap fill structure 521.

A conductive material layer may be formed on the substrate having the preliminary gap fill structure 521, and an uppermost interlayer insulating layer 506f of the interlayer insulating layers 506a to 506f may be planarized to form a pad conductive layer 524. During the planarization process for forming the pad conductive layer 524, a semiconductor layer disposed on an uppermost interlayer insulating layer 506f of the interlayer insulating layers 506a to 506f may be removed. Therefore, the semiconductor layer 512 may have a bottom part 512′ covering a sidewall of the opening 509 and a bottom part of the preliminary gap fill structure 521.

Afterwards, the interlayer insulating layers 506a to 506f and the sacrificial layers SC1 to SC6 may be patterned to form a preliminary isolation region 527 disposed between the openings 509 and exposing a top surface of the substrate 100. When viewed from a plan view, the preliminary isolation region 527 may be in the shape of a line.

Referring to FIGS. 16 and 17C, processes of removing the sacrificial layers SC1 to SC6, forming the gate insulating layer 130, and forming the conductive layer 133 described with reference to FIG. 12H, a process of anisotropically etching the conductive layer 133 described with reference to FIG. 12I, and a process of forming the gate isolation insulating layer 136 may be performed on the results where the preliminary isolation region 527 is formed. As a result, the interlayer insulating layers 506a to 506f may be formed as interlayer insulating patterns 506′ as illustrated in FIG. 17C. A gate insulating layer 530 described with reference to FIG. 12H may be formed on the results where the sacrificial layers SC1 to SC6 are removed. Conductive patterns 534 may be formed in an empty space formed by removing the sacrificial layers SC1 to SC6 as described with reference to FIG. 12I. The conductive patterns 534 and the interlayer insulating patterns 506′ may be defined as horizontal patterns 535. Thereafter, a gate isolation insulating layer 536 filling the preliminary isolation region 527 as described with reference to FIG. 12J may be formed.

Referring to FIG. 17D, the semiconductor layer 512, the preliminary gap fill structure 521, and the pad conductive layer 524 formed in the opening in the shape of a line may be patterned to form a semiconductor pattern 512a, a gap fill structure 521′ and a pad pattern 524′ in the opening 509, respectively. Further, empty spaces 539 may be formed between the horizontal patterns 535 and between structures formed of the semiconductor pattern 512a, the gap fill structure 521′ and the pad pattern 524′.

The semiconductor pattern 512a may be formed along sidewalls of the horizontal patterns 535 adjacent to the opening 509, and may have a bottom part 512a′ extending towards a bottom part of the opening 509. Both facing sidewalls of the gap fill structure 521′ may be covered with the semiconductor pattern 512a. Sidewalls of the gap fill structure 521′, which are not covered with the semiconductor pattern 512a, may be exposed to the empty space 539. As described in the previous embodiments, in particular, in FIG. 10A, the gap fill structure 521′ may include first and second gap fill patterns 515′ and 519′. The pad pattern 524′ may cover a top surface of the gap fill structure 521′.

Referring to FIG. 17E, insulating pillars 542 filling the empty space 539 may be formed. The insulating pillars 542 may be disposed between the horizontal patterns 535 and between structures including the semiconductor pattern 512a, the gap fill structure 521′, and the pad pattern 524′.

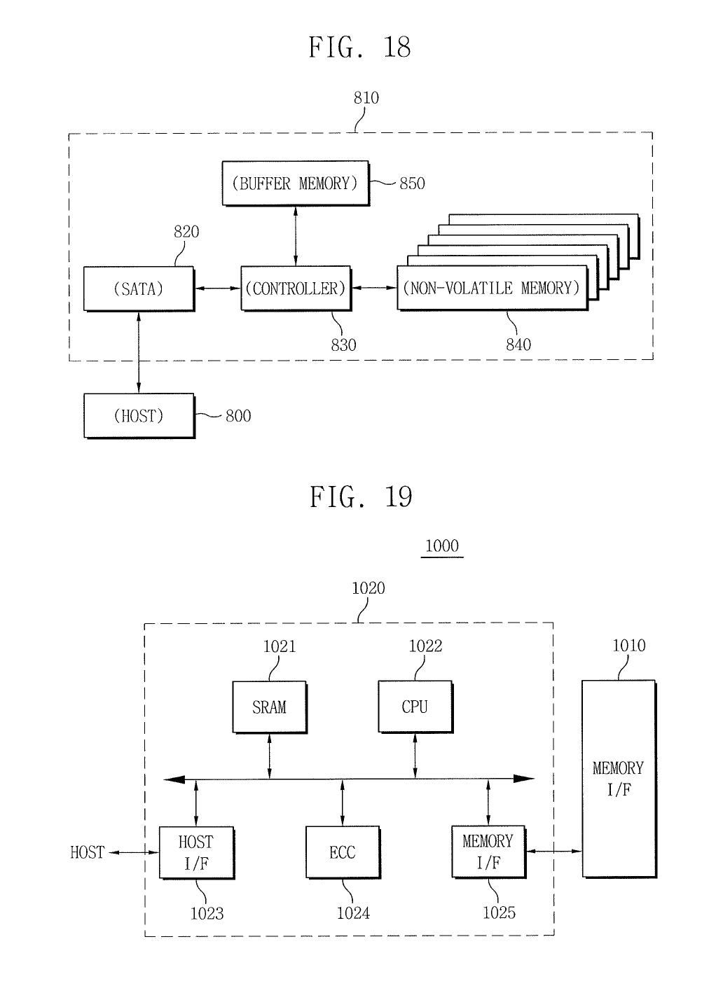

FIG. 18 illustrates a schematic block diagram of an electronic system employing a semiconductor device according to exemplary embodiments. The electronic system may be a data storage device, e.g., a solid state disk (SSD) 810.

Referring to FIG. 18, the SSD 810 may include an interface 820, a controller 830, a non-volatile memory 840, and a buffer memory 850. The non-volatile memory 840 may be an element fabricated according one of the exemplary embodiments discussed above.

The SSD 810 may be a device that stores data using, e.g., a semiconductor. The SSD 810 may have superior characteristics, e.g., as compared to a hard disk drive (HDD), in terms of, e.g., speed, mechanical delay, error rate, generation of heat, noise, size, and/or weight. The SSD 810 may be used for, e.g., a notebook PC, a desk top PC, an MP3 player, or a portable storage device.

The controller 830 may be formed adjacent to the interface 820 and electrically connected thereto. The controller 830 may include a memory controller and a buffer controller. The non-volatile memory 840 may be formed adjacent to the controller 830 and electrically connected thereto. A data storage capacity of the SSD 810 may correspond to the non-volatile memory 840. The buffer memory 850 may be foamed adjacent to the controller 830 and electrically connected thereto.

The interface 820 may be connected to a host 800. The interface 820 may function to, e.g., transmit and receive electrical signals such as data. For example, the interface 820 may be a device that uses a standard, e.g., SATA, IDE, SCSI and/or a combination thereof. The non-volatile memory 840 may be connected to the interface 820 via, e.g., the controller 830. The non-volatile memory 840 may function to store data received via the interface 820. The non-volatile memory 840 may be characterized by maintaining data stored therein, e.g., even when power supplied to the SSD 810 is completely cut off.

The buffer memory 850 may include a volatile memory. The volatile memory may be, e.g., a dynamic random access memory (DRAM) and/or a static random access memory (SRAM). The buffer memory 850 may exhibit a higher operating rate than, e.g., the non-volatile memory 840.

A data processing rate of the interface 820 may be higher than the operating rate of the non-volatile memory 840. The buffer memory 850 may function to preliminarily store data. The data received via the interface 820 may be preliminarily stored in the buffer memory 850 via the controller 830, and may keep pace with a data writing rate of the non-volatile memory 840 to be stored, e.g., permanently stored, in the non-volatile memory 840. Data frequently used among data stored in the non-volatile memory 840 may be read in advance to be preliminarily stored in the buffer memory 850. That is, the buffer memory 850 may function to increase an effective operating rate of the SSD 810 and to reduce an error rate.

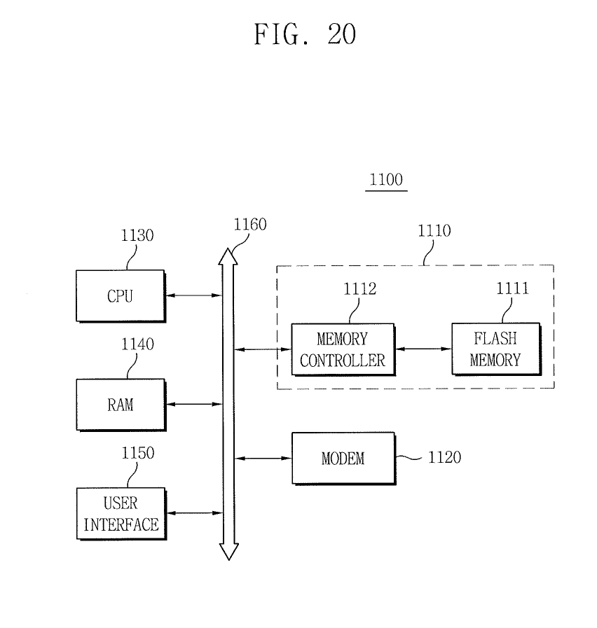

FIG. 19 illustrates a block diagram of a memory card including a non-volatile memory device according to an exemplary embodiment.

Referring to FIG. 19, a memory card 1000 for supporting high-capacity data storage capabilities may include a flash memory 1010. The flash memory 1010 may include a semiconductor device according to one of the above-described embodiments, i.e., a non-volatile memory device. For example, the flash memory 1010 may include an NAND-type flash memory device according to one of the above-described embodiments.

The memory card 1000 may include a memory controller 1020. The memory controller 1020 may controlling various data exchanges between a host and the flash memory 1010. An SRAM 1021 may be used as an operation memory of a central processing unit (CPU) 1022. A host interface 1023 may include a data exchange protocol of the host connected to the memory card 1000. An error correction code (ECC) 1024 may detect and correct errors included in data read from the flash memory 1010. A memory interface 1025 may interface with the flash memory 1010. The CPU 1022 may perform various control operations for, e.g., exchanging data of the memory controller 1020. While it is not illustrated in the drawing, the memory card 1000 may further include a ROM storing code data for interfacing with the host.

FIG. 20 illustrates a block diagram of a data processing system according to an exemplary embodiment.

Referring to FIG. 20, a data processing system 1100 may include a flash memory system 1110 including, e.g., a non-volatile memory device according to one of the exemplary embodiments discussed above. For examples, the flash memory system 1110 may include a flash memory device such as a NAND flash memory device. The flash memory system 1110 may include a memory controller 1112 and a flash memory 1111.

The data processing system 1100 may include, e.g., a mobile device or a computer. For example, the data processing system 1100 may include a modem 1120, a CPU 1130, a RAM 1140, and a user interface 1150 that are electrically connected to the flash memory system 1110 and a system bus 1160. The flash memory system 1110 may, e.g., store data processed by the CPU 1130 or data input from the outside.

The data processing system 1100 may be provided to, e.g., a memory card, a solid state disk (SSD), a camera image sensor, or other application chipsets. For example, the flash memory system 1110 may be formed of an SSD, and in this case, the data processing system 1100 may store large-capacity data in the flash memory system 1110 in a stable and reliable manner.

The flash memory or the flash memory system according to one of the exemplary embodiments may be mounted as a package in various forms. For example, the flash memory or the flash memory system may be packaged using at least one of a package on package, ball grid arrays, chip scale packages, a plastic leaded chip carrier, a plastic dual in-line package, a multi chip package, a wafer level package, a wafer level fabricated package, a wafer level processed stack package, a die on waffle package, a die in wafer form, a chip on board, a ceramic dual in-line package, a plastic metric quad flat pack, a thin quad flat pack, a small outline package, a shrink small outline package, a thin small outline package, a thin quad flat package, and a system in package.

By way of summation and review, the manufacture of a memory devices, e.g., vertical-NAND (V-NAND) device having a macaroni channel structure, may include forming a channel hole, forming a channel polysilicon (poly-Si) layer on a sidewall of the channel hole, forming an oxide layer to partially fill the channel hole, and forming a pad poly-Si layer to fill the remaining portion of the channel hole. However, forming the oxide layer oxide may include partially etching the oxide layer. In this case, undesired oxide may remain between the pad poly-Si layer and the channel poly-Si layer. The remaining oxide may increase resistance between a channel and a pad and may deteriorate on-current characteristics of the V-NAND device. Furthermore, deviation failures may occur, depending on the thickness of the remaining oxide.

In contrast, embodiments, e.g., the exemplary embodiments discussed above, may include a semiconductor device having a semiconductor pattern formed of first crystalline silicon in contact, e.g., stable contact, with a pad pattern formed of second crystalline silicon.

Embodiments may include a semiconductor device having a gap fill structure that includes upper and lower parts, and the upper and lower parts may be different from each other. Sidewalls of the gap fill structure may be covered with layers formed of crystalline silicon, and the gap fill structure may be substantially free of voids therein. Embodiments may include a manufacturing method capable of reducing the possibility of and/or preventing the deterioration of a semiconductor pattern used as a channel region. Embodiments are not limited to the above, and other embodiments may be apparently understood by one of ordinary skill in the art.

The foregoing is illustrative of embodiments and is not to be construed as limiting thereof. Although a few embodiments have been described, those skilled in the art will readily appreciate that many modifications are possible in embodiments without materially departing from the novel teachings and advantages. Accordingly, all such modifications are intended to be included within the scope as defined in the claims. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A semiconductor device, comprising:
horizontal patterns on a substrate, the horizontal patterns having at least one opening therein;
a pad pattern in an upper region of the at least one opening;
an insulating gap fill structure in the at least one opening, the insulating gap fill structure being between the pad pattern and the substrate, and the insulating gap fill structure including a first gap fill pattern and a second gap fill pattern; and
a semiconductor pattern, the semiconductor pattern being between a sidewall of the gap fill structure and sidewalls of the horizontal patterns and being between a sidewall of the pad pattern and the sidewalls of the horizontal patterns,
the first gap fill pattern including a first oxide and the second gap fill pattern including a second oxide, the second oxide having a different etching selectivity from that of the first oxide.

2. The device as claimed in claim 1, further comprising a bottom part of the semiconductor pattern, the bottom part being interposed between the gap fill structure and the substrate.

3. The device as claimed in claim 1, wherein:
the first gap fill pattern includes a first silicon oxide and at least a first type of impurity in the first silicon oxide, and
the second gap fill pattern includes a second silicon oxide and at least a second type of impurity in the second silicon oxide, the second type of impurity being different from the first type of impurity.

4. The device as claimed in claim 1, wherein:
the first gap fill pattern includes a first silicon oxide and hydrogen and chlorine as impurities in the first silicon oxide, and
the second gap fill pattern includes a second silicon oxide and at least one of nitrogen, hydrogen, and carbon as impurities in the second silicon oxide.

5. The device as claimed in claim 1, wherein:
a top surface of the first gap fill pattern includes a middle part that is concavely recessed, and
the second gap fill pattern is interposed between the first gap fill pattern and the pad pattern.

6. The device as claimed in claim 1, the second gap fill pattern has a pillar shape, and the first gap fill pattern surrounds a sidewall of the second gap fill pattern.

7. The device as claimed in claim 1, wherein the at least one opening is in a shape of a hole in the horizontal patterns.

8. The device as claimed in claim 1, wherein the at least one opening is in a shape of a line when viewed from a plan view, and the opening crosses the horizontal patterns.

9. The device as claimed in claim 1, wherein the horizontal patterns include a plurality of conductive patterns and a plurality of insulating patterns alternately stacked, an uppermost layer of the horizontal patterns being one of the plurality of insulating patterns, and a lowermost conductive pattern of the plurality of conductive patterns being spaced apart from the substrate.

10. The device as claimed in claim 9, further comprising a gate insulating layer between the conductive patterns and the semiconductor pattern.

11. The device as claimed in claim 10, wherein the gate insulating layer extends between the conductive patterns and the insulating patterns.

12. The device as claimed in claim 10, wherein the gate insulating layer is between the semiconductor pattern and the conductive patterns and is between the semiconductor pattern and the insulating patterns.

13. The device as claimed in claim 10, wherein the semiconductor pattern corresponds to a channel region of a transistor, the gate insulating layer includes a data storage layer data of a non-volatile memory cell, and the conductive patterns correspond to gate electrodes.

14. A semiconductor device, comprising:
horizontal patterns on a semiconductor substrate, the horizontal patterns including alternately stacked gate electrodes and insulating patterns;
at least one opening penetrating the horizontal patterns, the opening exposing the semiconductor substrate;
a pad pattern in an upper region of the at least one opening, the pad pattern including a first crystalline silicon;
a gap fill structure in the at least one opening, the gap fill structure being between the pad pattern and the semiconductor substrate, and the gap fill structure including a first gap fill pattern containing a first oxide and a second gap fill pattern containing a second oxide, the second oxide having a different etching selectivity from that of the first oxide;
a semiconductor pattern, the semiconductor pattern including a second crystalline silicon, and the semiconductor pattern being between a sidewall of the gap fill structure and sidewalls of the horizontal patterns and being between the pad pattern and the sidewalls of the horizontal patterns;
impurity regions in the pad pattern and the semiconductor pattern adjacent to the pad pattern; and
a gate insulating layer between the semiconductor pattern and the gate electrodes, the gate insulating layer including a data storage layer.

15. The device as claimed in claim 14, wherein, in the at least one opening, sidewalls of the gate electrodes are not vertically aligned with sidewalls of the insulating patterns.

16. The device as claimed in claim 14, wherein, in the at least one opening, sidewalls of the gate electrodes are vertically aligned with sidewalls of the insulating patterns.

17. A semiconductor device, comprising:
a stacked structure including a plurality of conductive patterns and a plurality of insulating patterns alternately stacked;
at least one opening in the stacked structure;
a semiconductor pattern on sidewalls of the at least one opening, the semiconductor pattern including crystalline silicon; and
an insulating gap fill structure on the semiconductor pattern and in the at least one opening, the insulating gap fill structure including:
a first gap fill pattern including a first oxide, and
a second gap fill pattern including a second oxide, the second oxide having a different etching selectivity from that of the first oxide.

18. The device as claimed in claim 17, wherein:
the first gap fill pattern is a first film in the at least one opening and the second gap fill pattern is a second film in the at least one opening, the second film being different from the first film, and
the second film is a flowable oxide film or a tonen silazene film.

19. The device as claimed in claim 18, further comprising a pad pattern in an uppermost portion of the at least one opening, the pad pattern, the first gap fill pattern, and the second gap fill pattern completely filling the at least one opening.

20. The device as claimed in claim 18, wherein the crystalline silicon of the semiconductor pattern is a crystalline silicon film, and the first and second gap fill patterns are directly on the crystalline silicon film.
